(19) United States
(12) Patent Application Publication
(10) Pub. No.: US 2026/0271458 A1
(43) Pub. Date: Sep. 10, 2026

(54) DISPLAY DEVICE, ELECTRONIC DEVICE AND METHOD FOR MANUFACTURING DISPLAY DEVICE

(71) Applicant: Samsung Display Co., Ltd., Yongin-si (KR)

(72) Inventors: Jong Moo HUH, Yongin-si (KR); Kyung Rock SON, Yongin-si (KR); Jae Phil LEE, Yongin-si (KR)

(21) Appl. No.: 19/423,491

(22) Filed: Dec. 17, 2025

(30) Foreign Application Priority Data
Mar. 6, 2025 (KR) 10-2025-0028974
Apr. 8, 2025 (KR) 10-2025-0045334

(51) Int. Cl. H10H 29/80; H10H 29/01; H10H 29/39

(52) U.S. Cl. CPC H10H 29/8321; H10H 29/012; H10H 29/032; H10H 29/39

(57) ABSTRACT

A display device comprising: sub-pixels in a display area, wherein each of the sub-pixels comprises: a pixel electrode on a substrate; a common electrode spaced from the pixel electrode on the substrate and comprising a branch extending to a periphery of the pixel electrode; and a tandem light emitting element on the pixel electrode and the common electrode, the tandem light emitting element comprising a first electrode bonded to the pixel electrode, a second electrode bonded to the common electrode, a first light emitting element on the first electrode, and a second light emitting element on the second electrode, and wherein at least one sub-pixel of the sub-pixels comprises a repair pattern on the first light emitting element and the branch of the common electrode, the repair pattern electrically connecting the first light emitting element and the common electrode.

### CROSS-REFERENCE TO RELATED APPLICATION

This application claims priority to and the benefit of Korean Patent Application No. 10-2025-0028974, filed on Mar. 6, 2025, and Korean Patent Application No. 10-2025-0045334, filed on Apr. 8, 2025, in the Korean Intellectual Property Office, the entire disclosure of all of which is incorporated by reference herein.

### BACKGROUND

### 1. Field

The present disclosure relates to a display device and an electronic device capable of displaying an image, and a method for manufacturing the display device.

### 2. Description of the Related Art

As the information society develops, various types of display devices and electronic devices capable of displaying images are being developed. The display device may be provided alone or may be included in an electronic device and used as a display screen of the electronic device.

The display device and the electronic device may include pixels that emit light in response to driving signals. Each pixel may include a plurality of sub-pixels to emit light of various colors, including standard white. Some display devices and electronic devices may use an inorganic light emitting element, such as micro a light emitting diode (Micro-LED), as a light source for sub-pixels.

### SUMMARY

Aspects and features of embodiments of the present disclosure provide a display device and an electronic device capable of improving manufacturing efficiency by efficiently repairing defects in sub-pixels including light emitting elements, and a method for manufacturing the display device.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device comprising: sub-pixels in a display area, wherein each of the sub-pixels comprises: a pixel electrode on a substrate; a common electrode spaced from the pixel electrode on the substrate and comprising a branch extending to a periphery of the pixel electrode; and a tandem light emitting element on the pixel electrode and the common electrode, the tandem light emitting element comprising a first electrode bonded to the pixel electrode, a second electrode bonded to the common electrode, a first light emitting element on the first electrode, and a second light emitting element on the second electrode, and wherein at least one sub-pixel of the sub-pixels comprises a repair pattern on the first light emitting element and the branch of the common electrode, the repair pattern electrically connecting the first light emitting element and the common electrode.

According to one or more embodiments, in the tandem light emitting element of the at least one sub-pixel, the first light emitting element is configured to emit light in response to a driving signal applied to the at least one sub-pixel, and the second light emitting element does not emit light.

According to one or more embodiments, another sub-pixel from among the sub-pixels do not include the repair pattern, and wherein the first light emitting element of the tandem light emitting element in the another sub-pixel is electrically connected to the common electrode via the second light emitting element of the tandem light emitting element.

According to one or more embodiments, in the tandem light emitting element of the another sub-pixel, the first light emitting element and the second light emitting element are configured to concurrently emit light in response to a driving signal applied to the another sub-pixel.

According to one or more embodiments, a portion of a lower surface of the first light emitting element is located in an area overlapping the pixel electrode, and wherein another portion of the lower surface of the first light emitting element is located in an area between the branch of the common electrode and the pixel electrode.

According to one or more embodiments, the repair pattern comprises a conductive dot covering a portion of an upper surface and a portion of a side surface of the first light emitting element of the tandem light emitting element of the at least one sub-pixel, and a portion of the branch.

According to one or more embodiments, the first electrode is on a portion of the lower surface of the first light emitting element, and wherein the repair pattern is spaced from the first electrode of the tandem light emitting element of the at least one sub-pixel.

According to one or more embodiments, the tandem light emitting element further comprises a connection electrode that connects the first light emitting element and the second light emitting element in series.

According to one or more embodiments, the tandem light emitting element further comprises a filling layer located between the first light emitting element and the second light emitting element, and wherein the first light emitting element and the second light emitting element are horizontally coupled with the filling layer interposed therebetween.

According to one or more embodiments, each of the first light emitting element and the second light emitting element comprises a first semiconductor layer comprising a first conductive dopant, an active layer on the first semiconductor layer, and a second semiconductor layer on the active layer and comprising a second conductive dopant, wherein the first electrode is electrically connected to the first semiconductor layer of the first light emitting element, and wherein the second electrode is electrically connected to the second semiconductor layer of the second light emitting element.

According to one or more embodiments, the repair pattern is on the second semiconductor layer of the first light emitting element.

According to one or more embodiments, an electronic device comprising: a display module comprising a display panel comprising sub-pixels; and a processor configured to transmit an image data signal to the display module, wherein each of the sub-pixels comprises: a pixel electrode on a substrate; a common electrode spaced from the pixel electrode on the substrate and comprising a branch extending to a periphery of the pixel electrode; and a tandem light emitting element on the pixel electrode and the common electrode, the tandem light emitting element comprising a first electrode bonded to the pixel electrode, a second electrode bonded to the common electrode, a first light emitting element on the first electrode, and a second light emitting element on the second electrode, and at least one sub-pixel of the sub-pixels comprises a repair pattern on the first light emitting element and the branch of the common electrode, the repair pattern electrically connecting the first light emitting element and the common electrode.

According to one or more embodiments, in the tandem light emitting element of the at least one sub-pixel, the first light emitting element is configured to emit light in response to a driving signal applied to the at least one sub-pixel, and the second light emitting element does not emit light.

According to one or more embodiments, another sub-pixel from among the sub-pixels do not include the repair pattern, and wherein the first light emitting element of the tandem light emitting element of the another sub-pixel is electrically connected to the common electrode via the second light emitting element of the tandem light emitting element.

According to one or more embodiments, the tandem light emitting element of the another sub-pixel, the first light emitting element and the second light emitting element are configured to concurrently emit light in response to a driving signal applied to the another sub-pixel.

According to one or more embodiments, a portion of a lower surface of the first light emitting element is located in an area overlapping the pixel electrode, and wherein another portion of the lower surface of the first light emitting element is located in an area between the branch of the common electrode and the pixel electrode.

According to one or more embodiments, the repair pattern comprises a conductive dot covering a portion of an upper surface and a portion of a side surface of the first light emitting element of the tandem light emitting element of the at least one sub-pixel, and a portion of the branch.

According to one or more embodiments, a method for manufacturing a display device comprising sub-pixels, the method comprising: forming a backplane substrate comprising a pixel electrode of each of the sub-pixels, and a common electrode spaced from the pixel electrode and comprising a branch extending to a periphery of the pixel electrode; bonding a tandem light emitting element comprising a first light emitting element and a second light emitting element that are horizontally coupled, a first electrode on a lower surface of the first light emitting element, and a second electrode on a lower surface of the second light emitting element, onto the pixel electrode and the common electrode; detecting a defect in the tandem light emitting element; and forming a repair pattern on the tandem light emitting element in which the defect is detected, wherein the detecting of the defect in the tandem light emitting element comprises determining a defect in each of the first light emitting element and the second light emitting element, and when the second light emitting element from among the first light emitting element and the second light emitting element is determined to be defective, the first light emitting element is electrically connected to the common electrode by the repair pattern.

According to one or more embodiments, the forming of the repair pattern comprises dispensing a conductive dot on the branch of the common electrode and the first light emitting element.

According to one or more embodiments, the detecting of the defect in the tandem light emitting element comprises: detecting light emitting characteristics of the tandem light emitting element by applying a driving signal to the tandem light emitting element of each of the sub-pixels; and determining a defect in each of the first light emitting element and the second light emitting element by irradiating light on the tandem light emitting element that abnormally emits light in the detecting of the light emitting characteristics of the tandem light emitting element.

According to a display device, an electronic device, and a method for manufacturing the display device according to one or more embodiments, a defect of the sub-pixel including a tandem light emitting element may be efficiently repaired by utilizing a repair pattern such as a conductive dot. Accordingly, the manufacturing efficiency of the display device and the electronic device may be increased and the manufacturing costs may be reduced.

However, effects, aspects, and features according to one or more embodiments of the present disclosure are not limited to those discussed above and various other effects, aspects, and features are incorporated herein.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a plan view illustrating a display area of a display panel according to one or more embodiments;

FIG. 6 is a plan view illustrating a display area of a display panel according to one or more embodiments;

FIG. 7 is a cross-sectional view illustrating a display area of a display panel according to one or more embodiments;

FIG. 8 is a cross-sectional view illustrating an area A1 of FIG. 7 in detail;

FIG. 9 is an equivalent circuit diagram illustrating a sub-pixel including a defective tandem light emitting element;

FIG. 10 is a flowchart illustrating a method for manufacturing a display device according to one or more embodiments;

FIG. 11 is a plan view illustrating a display area of a display panel according to one or more embodiments;

FIG. 12 is a cross-sectional view illustrating a display area of a display panel according to one or more embodiments;

FIG. 13 is an equivalent circuit diagram illustrating a repaired sub-pixel according to one or more embodiments;

FIG. 14 is a block diagram of an electronic device according to one or more embodiments; and

FIG. 15 illustrates schematic diagrams of electronic devices according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

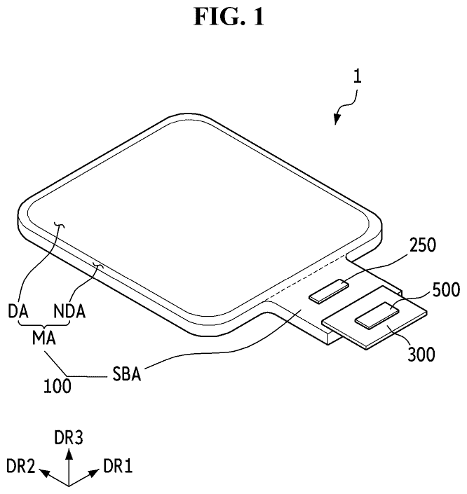

FIG. 1 is a perspective view illustrating a display device according to one or more embodiments.

Referring to FIG. 1, a display device 1 may be a device capable of providing an image such as a moving image and/or still image. For example, the display device 1 may be a device that includes a display module including a display panel 100 and may display an image accordingly. As an example, the display device 1 may refer to any electronic device that provides a display screen on which an image may be displayed or includes a display module for displaying an image.

The display device 1 may be provided alone or may be included in an electronic device providing a display screen to form a display screen of the electronic device. For example, the display device 1 may be included in various electronic devices, such as a television, a laptop computer, a monitor, a billboard, and/or Internet of Things (IoT) as well as portable electronic devices, such as a mobile phone, a smartphone, a tablet personal computer (PC), a smartwatch, a watch phone, a mobile communication terminal, an electronic organizer, an electronic book, a portable multimedia player (PMP), a navigation device, and an ultra-mobile PC (UMPC), and used as a display screen thereof. In addition, the display device 1 may also be included in other electronic devices, such as a virtual reality (VR) device or an augmented reality (AR) device, and used to display images in the electronic devices. In one or more embodiments, the electronic device including the display device 1 may further include a display device accommodating portion in which the display device 1 is accommodated, and/or a case or cover for protecting the display device 1.

FIG. 1 illustrates a display module, which is a main component of the display device 1. In one or more embodiments, the display device 1 (or the electronic device including the display module) may further include additional components. As an example, the display device 1 may further include a housing that accommodates the display module of FIG. 1.

In one or more embodiments, the display device 1 may be a light emitting display device, such as an organic light emitting display device using an organic light emitting diode (OLED), a quantum dot light emitting display device including a quantum dot light emitting layer, an inorganic light emitting display device including an inorganic semiconductor, and an ultra-small light emitting display device using an ultra-small light emitting diode (e.g., a micro light emitting diode (LED) or a nano LED). Hereinafter, as an example of the display device 1 to which the embodiments may be applied, a light emitting display device including an ultra-small light emitting diode will be disclosed. However, the type of light emitting element included in the display device 1 is not limited to the ultra-small light emitting diode, and the display device 1 may also include light emitting elements of other types and/or sizes.

The display device 1 may include a display panel 100, a display driving circuit 250, a circuit board 300, and a power supply unit 500 (also referred to as a “power supply circuit”).

The display panel 100 may be formed in a rectangular plane having sides in a first direction DR1 and sides in a second direction DR2 intersecting the first direction DR1. Corners where the sides in the first direction DR1 and the sides in the second direction DR2 meet may be formed in a rounded or angled shape. The planar shape of the display panel 100 is not limited to the quadrangular shape, and may be formed in another polygonal, circular, or elliptical shape. The display panel 100 may be formed to be substantially flat, but is not limited thereto. The display panel 100 may be entirely formed to be rigid, or may be flexibly formed so as to be able to be bent, curved, folded, or rolled at least in one portion.

The display panel 100 may include a main area MA and a sub-area SBA.

The main area MA may include a display area DA for displaying an image and a non-display area NDA which is a peripheral area of the display area DA. The display area DA may include pixels for displaying an image. Each of the pixels may include a plurality of sub-pixels. As an example, each of the pixels may include a first sub-pixel for emitting light of a first color, a second sub-pixel for emitting light of a second color, and a third sub-pixel for emitting light of a third color.

The sub-area SBA may protrude from one side of the main area MA in the second direction DR2. It is illustrated in FIG. 1 that the sub-area SBA is unfolded, but the sub-area SBA may be bent. When the sub-area SBA is bent, the main area MA and the sub-area SBA may overlap in a third direction DR3, which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and may be attached onto the display panel 100 in a chip on glass (COG) manner, a chip on plastic (COP) manner, or an ultrasonic bonding manner, but is not limited thereto. For example, the display driving circuit 250 may be attached onto the circuit board 300 in a chip on film (COF) manner.

The circuit board 300 may be attached to one end of the sub-area SBA. When the sub-area SBA is omitted, the circuit board 300 may be attached to one end of the main area MA (e.g., one end of the non-display area NDA). Therefore, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film such as a flexible printed circuit board (FPCB), a printed circuit board (PCB), or a chip on film.

The power supply unit 500 may generate a plurality of panel driving voltages according to a power voltage supplied from the outside. The power supply unit 500 may be formed as an integrated circuit (IC) and attached onto the circuit board 300 in a COF manner.

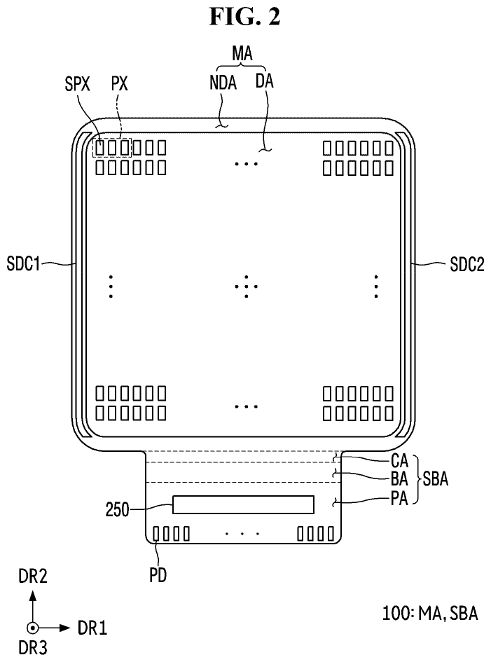

FIG. 2 is a layout view illustrating the display device according to one or more embodiments. It is illustrated in FIG. 2 that the sub-area SBA is unfolded without being bent.

Referring to FIGS. 2-4, the display panel 100 may include the main area MA and the sub-area SBA.

The main area MA may include a display area DA for displaying an image and a non-display area NDA which is a peripheral area of the display area DA. The display area DA may occupy most of the main area MA. The display area DA may be disposed at the center of the main area MA.

The display area DA may include pixels PX for displaying an image, and each of the pixels PX may include a plurality of sub-pixels SPX. The pixel PX may be defined as the smallest unit of sub-pixel group capable of expressing a white gray level (e.g., a white grayscale value).

The non-display area NDA may be disposed to be adjacent to the display area DA along an edge or a periphery of the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on one side (e.g., a left side) of the display panel 100, and the second scan driver SDC2 may be disposed on the other side (e.g., a right side) of the display panel, but the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from one side of the main area MA in the second direction DR2. A length of the sub-area SBA in the second direction DR2 may be smaller than the length of the main area MA in the second direction DR2. A length of the sub-area SBA in the first direction DR1 may be smaller than a length of the main area MA in the first direction DR1, or may be substantially the same as the length of the main area MA in the first direction DR1. The sub-area SBA may be bent and may be disposed below the display panel 100. In this case, the sub-area SBA may overlap the main area MA in the third direction DR3.

The sub-area SBA may include a connection area CA, a pad area PA, and a bending area BA.

The connection area CA is an area that protrudes from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads in the pad area PA using a conductive adhesive member such as an anisotropic conductive film. The circuit board 300 may be attached to the pads PD in the pad area PA using a conductive adhesive material such as an anisotropic conductive film. One side of the pad area PA may be in contact with the bending area BA.

The bending area BA is an area that is bent. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

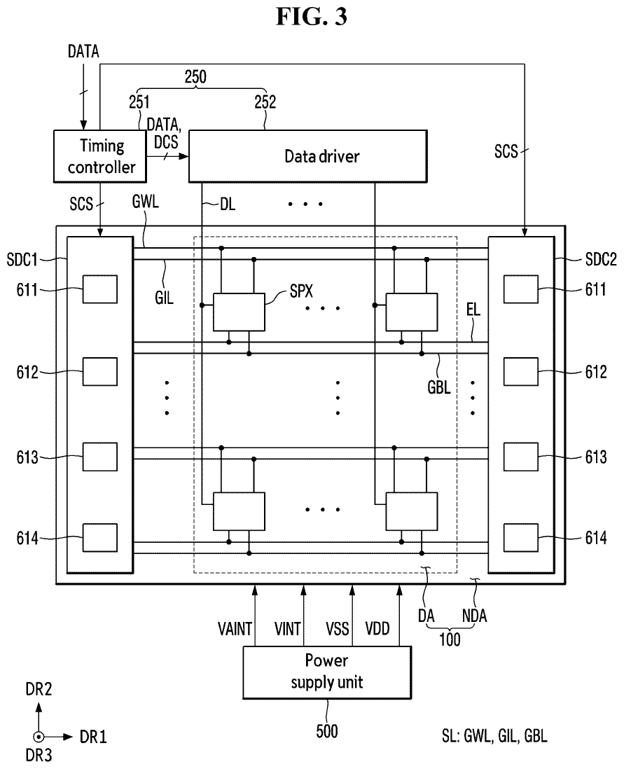

FIG. 3 is a block diagram illustrating the display device according to one or more embodiments.

Referring to FIG. 3 in addition to FIGS. 1 and 2, the display area DA may include pixels PX (each of the pixels PX including a plurality of sub-pixel SPX), scan lines SL, emission control lines EL, and data lines DL.

The pixels PX may be arranged in a matrix form along the first direction DR1 and the second direction DR2. For example, the plurality of pixels PX may be arranged along rows and columns of a matrix along the first direction DR1 and the second direction DR2, but are not limited thereto. The scan lines SL and the emission control lines EL may extend in the first direction DR1 and may be disposed along the second direction DR2. The data lines DL may extend in the second direction DR2 and may be disposed along the first direction DR1. In one or more embodiments, the scan lines SL may include write scan lines GWL, initialization scan lines GIL, and bias scan lines GBL.

Each of the plurality of sub-pixels SPX included in each of the pixels PX may be connected to one of the write scan lines GWL, one of the initialization scan lines GIL, one of the bias scan lines GBL, one of the emission control lines EL, and one of the data lines DL. In describing the embodiments, the term “connection” may include a direct connection or an indirect connection, and may include the meaning of an electrical and/or physical connection. Each of the plurality of sub-pixels SPX may receive a data voltage of the data line DL according to a write scan signal of the write scan line GWL, and may emit light from a light emitting element according to the data voltage.

The non-display area NDA includes a first scan driver SDC1, a second scan driver SDC2, and a display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing controller 251 (also referred to as a “timing control circuit”).

The write scan signal output unit 611 may generate write scan signals according to the scan timing control signal SCS of the timing controller 251 and sequentially output the write scan signals to the write scan lines GWL.

The initialization scan signal output unit 612 may generate initialization scan signals according to the scan timing control signal SCS and sequentially output the initialization scan signals to the initialization scan lines GIL.

The bias scan signal output unit 613 may generate bias scan signals according to the scan timing control signal SCS and sequentially output the bias scan signals to the bias scan lines GBL.

The emission control signal output unit 614 may generate emission control signals according to the scan timing control signal SCS and sequentially output the emission control signals to the emission control lines EL.

The display driving circuit 250 includes a timing controller 251 and a data driver 252 (also referred to as a “data driving circuit”).

The data driver 252 may receive digital video data DATA and a data timing control signal DCS from the timing controller 251. The data driver 252 converts the digital video data DATA into analog data voltages according to the data timing control signal DCS and outputs the converted analog data voltages to the data lines DL. In this case, the sub-pixels SPX may be selected by the write scan signals of the first scan driver SDC1 and the second scan driver SDC2, and the data voltages may be supplied to the selected sub-pixels SPX.

The timing controller 251 may receive digital video data DATA and timing signals from the outside. The timing controller 251 may generate a scan timing control signal SCS and a data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power voltage supplied from the outside. For example, the power supply unit 500 may generate a first driving voltage VDD, a second driving voltage VSS, a third driving voltage VINT, and a fourth driving voltage VAINT, and supply the generated driving voltages to the display panel 100.

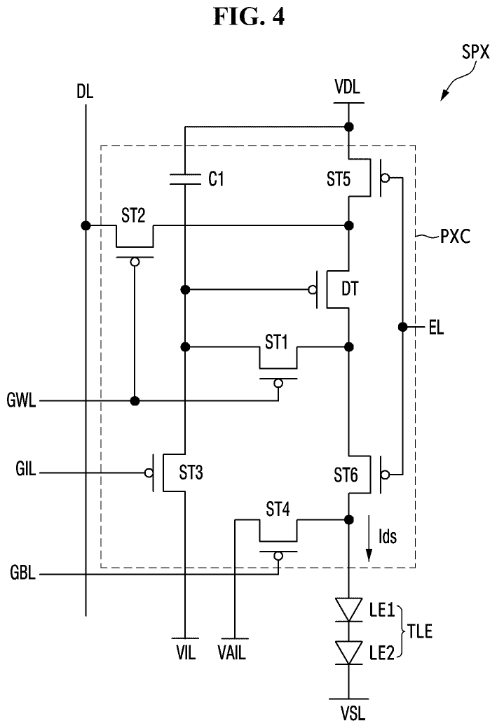

FIG. 4 is an equivalent circuit diagram illustrating a sub-pixel according to one or more embodiments.

Referring to FIG. 4 in addition to FIG. 3, the sub-pixel SPX according to one or more embodiments may be connected to the scan lines SL, the emission control line EL, and the data line DL. For example, the sub-pixel SPX may be connected to the write scan line GWL, the initialization scan line GIL, the bias scan line GBL, the emission control line EL, and the data line DL.

The sub-pixel SPX may include at least one light emitting element and a pixel circuit PXC electrically connected to the at least one light emitting element.

In one or more embodiments, the sub-pixel SPX may include a tandem structure of light emitting element TLE including a first light emitting element LE1 and a second light emitting element LE2. The first light emitting element LE1 and the second light emitting element LE2 may be connected in series between the pixel circuit PXC and a second power line VSL. In one or more embodiments, each of the first light emitting element LE1 and the second light emitting element LE2 may be a micro LED.

In one or more embodiments, the first light emitting element LE1 and the second light emitting element LE2 may each include a semiconductor stack and may be integrated into a single chip. In addition, the first light emitting element LE1 and the second light emitting element LE2 may have a form in which they are equivalently connected in series. For example, each of the first light emitting element LE1 and the second light emitting element LE2 may include a semiconductor stack in which a first semiconductor layer including a p-type dopant, an active layer (e.g., a light emitting layer), and a second semiconductor layer including an n-type dopant are stacked, and the semiconductor stack of the first light emitting element LE1 and the semiconductor stack of the second light emitting element LE2 may be connected in series between a pixel electrode connected to the pixel circuit PXC and a common electrode connected to the second power line VSL. In describing the embodiments, the tandem structure of light emitting element TLE described above is referred to as a “tandem light emitting element TLE.” The tandem light emitting element TLE according to one or more embodiments may be a flip-chip tandem micro-LED.

The tandem light emitting element TLE may be electrically connected to a driving transistor DT and may emit light with luminance corresponding to a driving current Ids controlled by the driving transistor DT. By utilizing the tandem light emitting element TLE as a light source of the sub-pixel SPX, the luminance of the sub-pixel SPX may be stably secured or improved. For example, in the sub-pixel SPX including the tandem light emitting element TLE, the first light emitting element LE1 and the second light emitting element LE2 may concurrently (e.g., simultaneously) emit light in response to the driving signal applied to the sub-pixel SPX. Accordingly, the luminance of the sub-pixel SPX may be improved.

The pixel circuit PXC may include circuit elements for supplying the driving current Ids to the tandem light emitting element TLE in response to the driving signals applied to the sub-pixel SPX. In one or more embodiments, each pixel PX may include a first sub-pixel, a second sub-pixel, and a third sub-pixel, and each of the first sub-pixel, the second sub-pixel, and the third sub-pixel may include a pixel circuit PXC and a tandem light emitting element TLE. In one or more embodiments, the first sub-pixel, the second sub-pixel, and the third sub-pixel may have the same equivalent circuit diagram.

The pixel circuit PXC may include a driving transistor DT, switch elements, and a capacitor C1. In one or more embodiments, the switch elements may include first to sixth transistors ST1, ST2, ST3, ST4, ST5, and ST6.

The driving transistor DT includes a gate electrode, a first electrode, and a second electrode. The driving transistor DT controls a driving current Ids flowing between the first electrode and the second electrode according to a data voltage applied to the gate electrode of the driving transistor DT.

The capacitor C1 is formed between the gate electrode of the driving transistor DT and a first power line VDL to which the first driving voltage (VDD in FIG. 3) is applied. The first driving voltage VDD may be a voltage of a higher level than the second driving voltage (VSS in FIG. 3). One electrode of the capacitor C1 may be connected to the gate electrode of the driving transistor DT, and the other electrode thereof may be connected to the first power line VDL.

In one or more embodiments, the first to sixth transistors ST1, ST2, ST3, ST4, ST5, and ST6, and the driving transistor DT may all be formed as p-type MOSFETs (e.g., p-type MOSFETs including polysilicon) as illustrated in FIG. 4. In another embodiment, at least one of the first to sixth transistors ST1, ST2, ST3, ST4, ST5, and ST6, and the driving transistor DT may also be formed as an n-type MOSFET (e.g., an n-type MOSFET including an oxide semiconductor).

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and the gate electrodes of the fifth and sixth transistors ST5 and ST6 may be connected to the emission control line EL. The first to sixth transistors ST1, ST2, ST3, ST4, ST5, and ST6 are formed as the P-type MOSFETs, and may thus be turned on when a scan signal and an emission control signal of a gate low voltage are applied to the initialization scan line GIL, the write scan line GWL, the bias scan line GBL, and the emission control line EL, respectively. One electrode of the third transistor ST3 may be connected to a first initialization voltage line VIL to which the third driving voltage (VINT in FIG. 3) is applied, and one electrode of the fourth transistor ST4 may be connected to a second initialization voltage line VAIL to which the fourth driving voltage (VAINT in FIG. 3) is applied. The third driving voltage VINT and the fourth driving voltage VAINT may be different voltages. In addition, the third driving voltage VINT and the fourth driving voltage VAINT may be voltages of a lower level than the first driving voltage VDD and may be voltages of a higher level than the second driving voltage VSS.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. In this case, because the first transistor ST1 and the third transistor ST3 are formed as the n-type MOSFETs, the first transistor ST1 may be turned on when a write scan signal of a gate high voltage is applied to the gate electrode, and the third transistor ST3 may be turned on when an initialization scan signal of a gate high voltage is applied to the gate electrode. In comparison, the second transistor ST2, the fourth transistor ST4, the fifth transistor ST5, and the sixth transistor ST6 are formed as the p-type MOSFETs, and may thus be turned on when a scan signal and an emission control signal of a gate low voltage are applied to the gate electrodes.

Alternatively, the fourth transistor ST4 may be formed as an n-type MOSFET, and the remaining transistors DT, ST1, ST2, ST3, ST5, and ST6 may be formed as p-type MOSFETs. In this case, the fourth transistor ST4 may be turned on when a scan signal of a gate high voltage is applied to the gate electrode, whereas the remaining transistors DT, ST1, ST2, ST3, ST5, and ST6 may be turned on when a scan signal of a gate low voltage and an emission control signal of a gate low voltage are applied to the gate electrodes.

Alternatively, the first to sixth transistors ST1, ST2, ST3, ST4, ST5, and ST6 and the driving transistor DT may all be formed as n-type MOSFETs. In this case, the first to sixth transistors ST1, ST2, ST3, ST4, ST5, and ST6 and the driving transistor DT may be turned on when a scan signal of a gate high voltage and an emission control signal of a gate high voltage are applied to the gate electrodes.

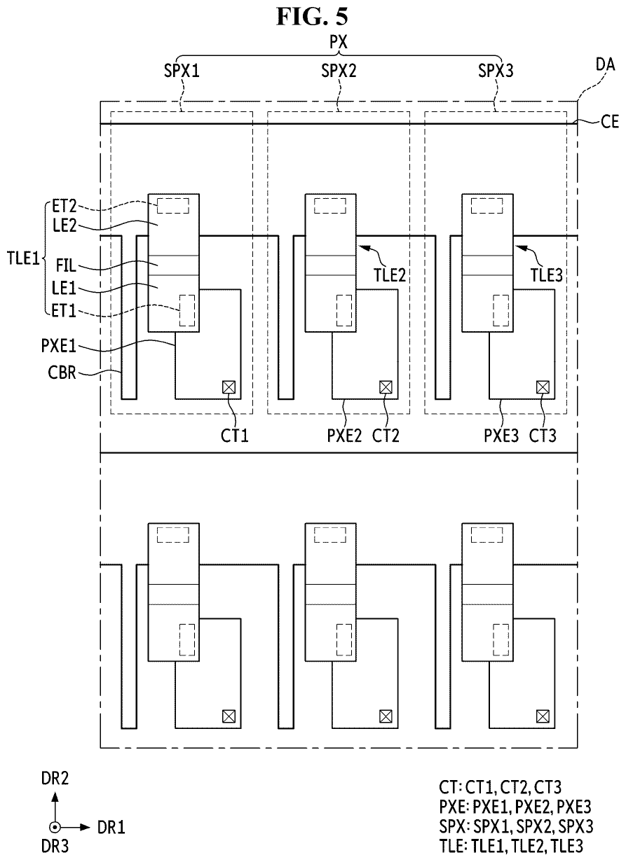

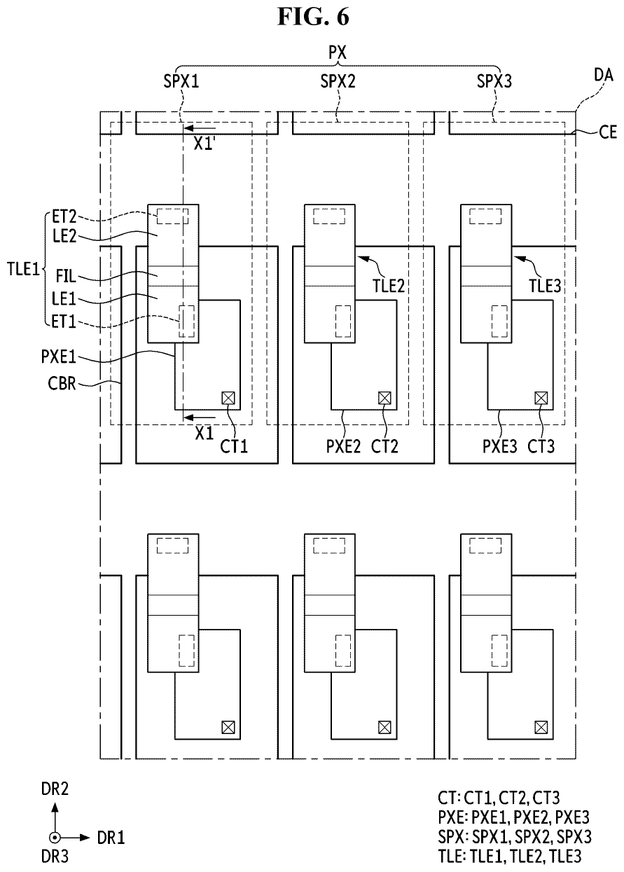

FIG. 5 is a plan view illustrating a display area of a display panel according to one or more embodiments. FIG. 6 is a plan view illustrating a display area of a display panel according to one or more embodiments. For example, FIGS. 5 and 6 illustrate a portion of the display area DA including two pixels PX sequentially disposed along the second direction DR2. FIGS. 5 and 6 illustrate different embodiments with respect to a branch CBR of a common electrode CE.

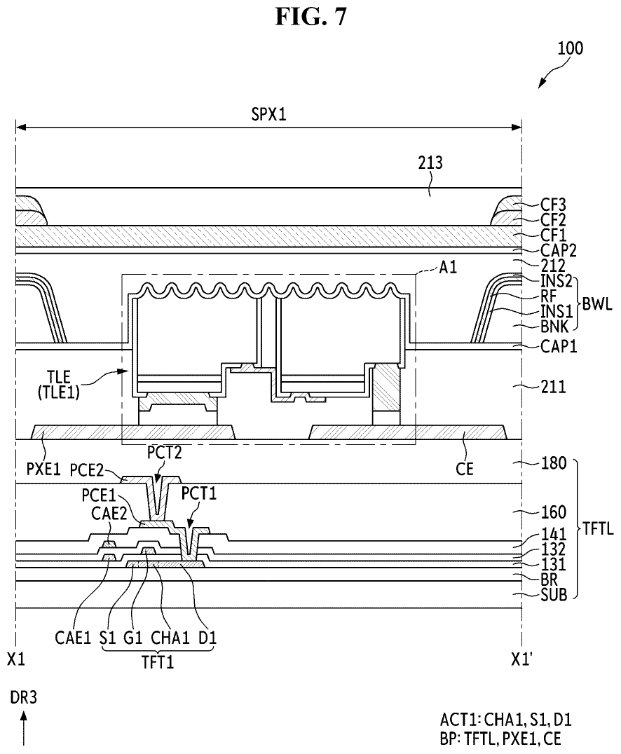

FIGS. 5 and 6 illustrate embodiments of a layout structure of a light emitting element layer including tandem light emitting elements TLE of the sub-pixels SPX among elements included in the display panel (100 in FIGS. 1-3). The display panel 100 may further include a panel circuit layer (e.g., a thin film transistor layer TFTL in FIG. 7) including circuit elements (e.g., the transistors and the capacitor C1 in FIG. 4) of each of the sub-pixels SPX.

Referring to FIGS. 5 and 6, each of the sub-pixels SPX may include a pixel electrode PXE and a tandem light emitting element TLE disposed on the pixel electrode PXE. In one or more embodiments, when the tandem light emitting element TLE is a flip-chip type light emitting element (e.g., a flip-chip type tandem micro LED), each of the sub-pixels SPX may further include a common electrode CE facing a lower surface of the tandem light emitting element TLE, similarly to the pixel electrode PXE.

In one or more embodiments, the sub-pixels SPX of each pixel PX may be arranged along the first direction DR1 and may share one common electrode CE. As an example, the common electrode CE may extend in the first direction DR1 in each pixel row (or horizontal line) of the display area DA, and the sub-pixels SPX of the pixels PX disposed in the corresponding pixel row may share one common electrode CE. The common electrode CE may be electrically connected to the second power line (VSL in FIG. 4) to which the second driving voltage (VSS in FIG. 3) is applied, within the display area DA and/or in the non-display area (NDA in FIGS. 1 to 3).

However, the shape or connection structure of the common electrode CE is not limited thereto. For example, the sub-pixels SPX of a pixel PX according to one or more other embodiments may also include respective common electrodes CE separated from each other. In this case, the common electrode CE may be formed separately for each sub-pixel SPX and may be electrically connected to the second power line (VSL in FIG. 4) through each contact hole and/or connection pattern.

In one or more embodiments, sub-pixels SPX that emit light of the same type and/or color from among the sub-pixels SPX of the display area DA may be sequentially or continuously arranged along the second direction DR2. As an example, the first sub-pixels SPX1 of the pixels PX included in each pixel column extending in the second direction DR2 in the display area DA may be sequentially or continuously arranged along the second direction DR2. In addition, the second sub-pixels SPX2 of the pixels PX included in each pixel column may be sequentially or continuously arranged along the second direction DR2, and the third sub-pixels SPX3 of the pixels PX included in each pixel column may be sequentially or continuously arranged along the second direction DR2. However, the arrangement of pixels PX and/or sub-pixels SPX may be variously changed depending on the embodiments.

The first sub-pixel SPX1 may include a first pixel electrode PXE1 and a common electrode CE (or a portion of the common electrode CE) that are spaced (e.g., spaced apart) from each other, and a first tandem light emitting element TLE1 disposed on the first pixel electrode PXE1 and the common electrode CE. The first pixel electrode PXE1 may refer to the pixel electrode PXE of the first sub-pixel SPX1, and the first tandem light emitting element TLE1 may refer to the tandem light emitting element TLE of the first sub-pixel SPX1. The first tandem light emitting element TLE1 may be electrically connected between the first pixel electrode PXE1 and the common electrode CE.

The second sub-pixel SPX2 may include a second pixel electrode PXE2 and a common electrode CE that are spaced (e.g., spaced apart) from each other, and a second tandem light emitting element TLE2 disposed on the second pixel electrode PXE2 and the common electrode CE. The second pixel electrode PXE2 may refer to the pixel electrode PXE of the second sub-pixel SPX2, and the second tandem light emitting element TLE2 may refer to the tandem light emitting element TLE of the second sub-pixel SPX2. The second tandem light emitting element TLE2 may be electrically connected between the second pixel electrode PXE2 and the common electrode CE.

The third sub-pixel SPX3 may include a third pixel electrode PXE3 and a common electrode CE that are spaced (e.g., spaced apart) from each other, and a third tandem light emitting element TLE3 disposed on the third pixel electrode PXE3 and the common electrode CE. The third pixel electrode PXE3 may refer to the pixel electrode PXE of the third sub-pixel SPX3, and the third tandem light emitting element TLE3 may refer to the tandem light emitting element TLE of the third sub-pixel SPX3. The third tandem light emitting element TLE3 may be electrically connected between the third pixel electrode PXE3 and the common electrode CE.

In one or more embodiments, the first pixel electrode PXE1, the second pixel electrode PXE2, and the third pixel electrode PXE3 of each pixel PX may be sequentially disposed along the first direction DR1 and spaced (e.g., spaced apart) from the common electrode CE in the second direction DR2. For example, the first pixel electrode PXE1, the second pixel electrode PXE2, and the third pixel electrode PXE3 may face different portions of the common electrode CE in the second direction DR2.

The pixel electrode PXE and the circuit elements of each of the sub-pixels SPX may be electrically connected to each other through at least one contact hole CT and/or connection pattern. For example, the first pixel electrode PXE1 of the first sub-pixel SPX1 may be electrically connected to at least one circuit element (e.g., the fourth and sixth transistors ST4 and ST6 in FIG. 4) included in the first sub-pixel SPX1 through a first contact hole CT1 and/or at least one connection pattern. Similarly, the second pixel electrode PXE2 of the second sub-pixel SPX2 may be electrically connected to at least one circuit element included in the second sub-pixel SPX2 through a second contact hole CT2 and/or at least one connection pattern, and the third pixel electrode PXE3 of the third sub-pixel SPX3 may be electrically connected to at least one circuit element included in the third sub-pixel SPX3 through a third contact hole CT3 and/or at least one connection pattern.

The tandem light emitting elements TLE of each of the sub-pixels SPX may be joined (e.g., bonded) to the pixel electrode PXE and the common electrode CE. For example, the tandem light emitting element TLE may include a first electrode ET1 and a second electrode ET2 disposed on a lower surface, the first electrode ET1 of the tandem light emitting element TLE may be bonded on the pixel electrode PXE, and the second electrode ET2 of the tandem light emitting element TLE may be bonded on the common electrode CE.

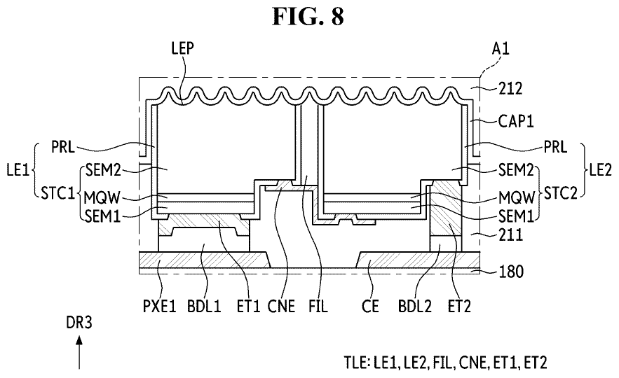

The tandem light emitting element TLE may include a first light emitting element LE1 disposed on the pixel electrode PXE, a second light emitting element LE2 disposed on the common electrode CE, and a filling layer FIL disposed between the first light emitting element LE1 and the second light emitting element LE2. Each of the first light emitting element LE1 and the second light emitting element LE2 may include a semiconductor stack including an active layer (e.g., a light emitting layer), and the first light emitting element LE1 and the second light emitting element LE2 may be electrically connected to each other by a connection electrode (e.g., the connection electrode CNE in FIG. 8).

The first electrode ET1 and the second electrode ET2 of the tandem light emitting element TLE may be electrically connected to the first light emitting element LE1 and the second light emitting element LE2, respectively. For example, the first electrode ET1 of the tandem light emitting element TLE may be disposed on a lower surface of the first light emitting element LE1 and electrically connected to the first light emitting element LE1, and the second electrode ET2 of the tandem light emitting element TLE may be disposed on a lower surface of the second light emitting element LE2 and electrically connected to the second light emitting element LE2. The first light emitting element LE1 may be electrically connected to the pixel electrode PXE through the first electrode ET1, and the second light emitting element LE2 may be electrically connected to the common electrode CE through the second electrode ET2.

Accordingly, the first light emitting element LE1 and the second light emitting element LE2 may be connected in series between the pixel electrode PXE and the common electrode CE. For example, the first light emitting element LE1 and the second light emitting element LE2 of the first tandem light emitting element TLE1 may be connected in series between the first pixel electrode PXE1 and the common electrode CE, the first light emitting element LE1 and the second light emitting element LE2 of the second tandem light emitting element TLE2 may be connected in series between the second pixel electrode PXE2 and the common electrode CE, and the first light emitting element LE1 and the second light emitting element LE2 of the third tandem light emitting element TLE3 may be connected in series between the third pixel electrode PXE3 and the common electrode CE.

In one or more embodiments, the common electrode CE may include a branch CBR extending around the periphery of the pixel electrode PXE of each of the sub-pixels SPX. For example, the common electrode CE may include a branch CBR extending in the second direction DR2 and positioned on one side of the pixel electrode PXE and the tandem light emitting element TLE, in each sub-pixel area where each pixel electrode PXE is disposed. As an example, the common electrode CE may include a branch CBR positioned on the left side of the pixel electrode PXE in each sub-pixel area and spaced (e.g., spaced apart) from the pixel electrode PXE in the first direction DR1.

In one or more embodiments, the branch CBR of the common electrode CE may be individually formed in each sub-pixel area, as illustrated in FIG. 5. In one or more other embodiments, the branch CBR of the common electrode CE may extend in the second direction DR2 as illustrated in FIG. 6 to meet the common electrode CE disposed in the sub-pixels SPX of the next pixel row. In this case, the common electrode CE may entirely have a mesh shape.

The tandem light emitting element TLE may be biased closer to the branch CBR of the common electrode CE in the first direction DR1. For example, in the first direction DR1, a portion of the first light emitting element LE1 may be disposed in an area between the branch CBR of the common electrode CE and the pixel electrode PXE, and another portion of the first light emitting element LE1 may be disposed in an area where the pixel electrode PXE is disposed.

In one or more embodiments, the tandem light emitting element TLE may be disposed at a position suitable for easily connecting the branch CBR of the common electrode CE and the first light emitting element LE1 by a repair pattern described later. For example, the tandem light emitting element TLE may be spaced (e.g., spaced apart) from the branch CBR of the common electrode CE by a distance suitable for easily connecting the branch CBR of the common electrode CE and the first light emitting element LE1 by dispensing a conductive dot (or conductive dots).

In one or more embodiments, the first electrode ET1 of the tandem light emitting element TLE may be disposed to be biased to a portion overlapping the pixel electrode PXE on the lower surface of the first light emitting element LE1. As an example, the first electrode ET1 of the tandem light emitting element TLE may have a rectangular planar shape extending in the second direction DR2 and may be disposed closer to a right end than a left end of the tandem light emitting element TLE. Accordingly, a bonding area between the first electrode ET1 of the tandem light emitting element TLE and the pixel electrode PXE may be secured, and a separation distance between the first electrode ET1 of the tandem light emitting element TLE and the branch CBR of the common electrode CE may be stably secured, thereby preventing a short circuit defect.

However, the present disclosure is not limited thereto. As an example, a portion of the first electrode ET1 of the tandem light emitting element TLE may also be disposed in an area between the branch CBR of the common electrode CE and the pixel electrode PXE. The size, position, and/or shape of the first electrode ET1 of the tandem light emitting element TLE may be changed or adjusted within a range suitable to ensure electrical stability between the first electrode ET1 of the tandem light emitting element TLE and the common electrode CE. As an example, the first electrode ET1 of the tandem light emitting element TLE may have a rectangular planar shape extending in the first direction DR1, but may be spaced (e.g., spaced apart) from the left end of the tandem light emitting element TLE by a certain distance or more.

Each of the tandem light emitting elements TLE may emit light of a particular color (e.g., red light, green light, blue light, or white light). In one or more embodiments, the first tandem light emitting element TLE1, the second tandem light emitting element TLE2, and the third tandem light emitting element TLE3 may emit light of different colors. For example, the first tandem light emitting element TLE1, the second tandem light emitting element TLE2, and the third tandem light emitting element TLE3 may emit light of a first color (e.g., red light), light of a second color (e.g., green light), and light of a third color (e.g., blue light), respectively.

In one or more embodiments, the first tandem light emitting element TLE1, the second tandem light emitting element TLE2, and the third tandem light emitting element TLE3 may emit light of the same color (e.g., blue light or white light). In this case, on at least one tandem light emitting element TLE among the first sub-pixel SPX1, the second sub-pixel SPX2, and the third sub-pixel SPX3, a light conversion layer (e.g., a light conversion layer including wavelength conversion particles) may be disposed to convert light emitted from the tandem light emitting element TLE of the corresponding sub-pixel SPX into light corresponding to an emission color (or emission wavelength) of the corresponding sub-pixel SPX.

FIG. 7 is a cross-sectional view illustrating a display area of a display panel according to one or more embodiments. For example, FIG. 7 illustrates an embodiment of a cross section of a first sub-pixel SPX1 corresponding to the line X1 to X1′ in FIG. 6. In one or more embodiments, the first sub-pixel SPX1, the second sub-pixel SPX2, and the third sub-pixel SPX3 may have substantially identical or similar cross-sectional structures.

FIG. 8 is a cross-sectional view illustrating an area A1 of FIG. 7 in detail. For example, FIG. 8 illustrates a tandem light emitting element TLE (e.g., a first tandem light emitting element TLE1) disposed in area A1 in FIG. 7 in detail. In one or more embodiments, the first tandem light emitting element TLE1, the second tandem light emitting element TLE1, and the third tandem light emitting element TLE3 may have substantially the same cross-sectional structure.

Referring to FIGS. 7 and 8 in addition to FIGS. 1-6, the display panel 100 according to one or more embodiments may include a thin film transistor layer TFTL including circuit elements of a sub-pixels SPX on a substrate SUB, pixel electrodes PXE and a common electrode CE disposed on the thin film transistor layer TFTL, and tandem light emitting elements TLE disposed on the pixel electrodes PXE and the common electrode CE. The thin film transistor layer TFTL, the pixel electrodes PXE, and the common electrode CE may form a backplane substrate BP of the display panel 100, and the tandem light emitting elements TLE of the sub-pixels SPX may be bonded on the backplane substrate BP. In one or more embodiments, the display panel 100 may further include a partition wall BWL disposed around the tandem light emitting elements TLE, and color filters disposed on the tandem light emitting elements TLE.

FIGS. 7 and 8 illustrate one thin film transistor TFT1 included in one first sub-pixel SPX1, as an example of the circuit elements disposed inside the thin film transistor layer TFTL. The thin film transistor TFT1 may be one of the transistors included in the first sub-pixel SPX1 (e.g., one of the driving transistor DT and the first to sixth transistors ST1, ST2, ST3, ST4, ST5, and ST6 in FIG. 4). In addition, FIGS. 7 and 8 illustrate a first pixel electrode PXE1 included in one first sub-pixel SPX1 and a portion of a common electrode CE facing the first pixel electrode PXE1, as an example of the pixel electrodes PXE and the common electrode CE disposed on the thin film transistor layer TFTL. The pixel electrodes PXE and the common electrode CE of the first sub-pixel SPX1, the second sub-pixel SPX2, and the third sub-pixel SPX3 may be disposed separately from each other in (e.g., on or at) the same layer.

In addition, FIGS. 7 and 8 illustrate a first tandem light emitting element TLE1 included in one first sub-pixel SPX1, as an example of the tandem light emitting elements TLE disposed on the backplane substrate BP. Each of the tandem light emitting elements TLE of the first sub-pixel SPX1, the second sub-pixel SPX2, and the third sub-pixel SPX3 may be disposed on the pixel electrode PXE of the corresponding sub-pixel SPX and a portion of the common electrode CE facing the pixel electrode PXE. The tandem light emitting elements TLE of the first sub-pixel SPX1, the second sub-pixel SPX2, and the third sub-pixel SPX3 may be bonded concurrently (e.g., simultaneously) or sequentially on the backplane substrate BP.

The substrate SUB may include an insulating material such as glass or a polymer resin. When the substrate SUB includes a polymer resin, the substrate SUB may be a flexible substrate that may be stretched. The polymer resin may be an acrylic resin, an epoxy resin, a phenolic resin, a polyamide resin, and/or a polyimide resin.

A barrier layer BR may be disposed on the substrate SUB. The barrier layer BR may protect the transistors of the thin film transistor layer TFTL and the tandem light emitting elements TLE on the thin film transistor layer TFTL from moisture permeating through the substrate SUB, which is vulnerable to moisture permeability. In one or more embodiments, the barrier layer BR may include a plurality of inorganic films alternately stacked.

The thin film transistor TFT1 may be disposed on the barrier layer BR. In one or more embodiments, the thin film transistor TFT1 may be one of the fourth transistor ST4 and the sixth transistor ST6 illustrated in FIG. 4. The thin film transistor TFT1 may include a first active layer ACT1 and a first gate electrode G1.

The first active layer ACT1 may be disposed on the barrier layer BR. The first active layer ACT1 may include polycrystalline silicon, single crystal silicon, low-temperature polycrystalline silicon, and/or amorphous silicon. Alternatively, the first active layer ACT1 of the thin film transistor TFT1 may include an oxide semiconductor (e.g., Indium Gallium Zinc Oxide (IGZO), Indium Gallium Zinc Tin Oxide (IGZTO), and/or Indium Gallium Tin Oxide (IGTO)).

The first active layer ACT1 may include a first channel region CHA1, a first source region S1, and a first drain region D1. The first channel region CHA1 may overlap the first gate electrode G1 in the third direction DR3 (e.g., a thickness direction of the substrate SUB). The first source region S1 may be disposed on one side of the first channel region CHA1, and the first drain region D1 may be disposed on the other side of the first channel region CHA1. At least a portion of the first source region S1 and the first drain region D1 may not overlap the first gate electrode G1 in the third direction DR3.

A first gate insulating layer 131 may be disposed on the first active layer ACT1 and on the barrier layer BR.

A first gate metal layer may be disposed on the first gate insulating layer 131. The first gate metal layer may include a first gate electrode G1 and a first capacitor electrode CAE1. The first gate electrode G1 may overlap the first channel region CHA1 of the first active layer ACT1 in the third direction DR3. In one or more embodiments, the first capacitor electrode CAE1 may be formed integrally with the gate electrode of the driving transistor DT of FIG. 4, and may be formed separately from the gate electrodes of the first to sixth transistors ST1, ST2, ST3, ST4, ST5, and ST6 of FIG. 4.

A second gate insulating layer 132 may be disposed on the first gate electrode G1 of the thin film transistor TFT1, the first capacitor electrode CAE1 and the first gate insulating layer 131.

A second gate metal layer may be disposed on the second gate insulating layer 132. The second gate metal layer may include a second capacitor electrode CAE2. The second capacitor electrode CAE2 may overlap the first capacitor electrode CAE1 in the third direction DR3. A capacitor (e.g., the capacitor C1 in FIG. 4) may be formed by the first capacitor electrode CAE1, the second capacitor electrode CAE2, and the second gate insulating layer 132 therebetween.

An interlayer insulating layer 141 may be disposed on the second capacitor electrode CAE2 and the second gate insulating layer 132.

A first data metal layer may be disposed on the interlayer insulating layer 141. The first data metal layer may include a first source connection electrode PCE1. The first source connection electrode PCE1 may be connected to the first drain region D1 of the thin film transistor TFT1 through a first source contact hole PCT1 penetrating through the first gate insulating layer 131, the second gate insulating layer 132, and the interlayer insulating layer 141.

A first planarization layer 160 may be disposed on the first source connection electrode PCE1 and the interlayer insulating layer 141. The first planarization layer 160 may alleviate or planarize a step difference caused by the thin film transistor TFT1.

A second data metal layer may be disposed on the first planarization layer 160. The second data metal layer may include a second source connection electrode PCE2. The second source connection electrode PCE2 may be connected to the first source connection electrode PCE1 through a second source contact hole PCT2 penetrating through the first planarization layer 160.

A second planarization layer 180 may be disposed on the second source connection electrode PCE2 and the first planarization layer 160. The second planarization layer 180 may alleviate or planarize a step difference caused by circuit elements and lines of the thin film transistor layer TFTL.

The barrier layer BR, the first gate insulating layer 131, the second gate insulating layer 132, and the interlayer insulating layer 141 may be formed as at least one inorganic insulating layer including an inorganic insulating material (e.g., silicon nitride (SiNₓ), silicon nitride oxide (SiON), silicon oxide (SiOₓ), titanium oxide (TiOₓ), and/or aluminum oxide (AlOₓ)). Each of the barrier layer BR, the first gate insulating layer 131, the second gate insulating layer 132, and the interlayer insulating layer 141 may be formed as a single-layer or multi-layer structure.

The first gate metal layer, the second gate metal layer, the first data metal layer, and the second data metal layer may include a conductive material (e.g., molybdenum (Mo), aluminum (Al), chromium (Cr), gold (Au), titanium (Ti), nickel (Ni), neodymium (Nd), and/or copper (Cu), and/or an alloy thereof). Each of the first gate metal layer, the second gate metal layer, the first data metal layer, and the second data metal layer may be formed as a single-layer or multi-layer structure.

The first planarization layer 160 and the second planarization layer 180 may include at least one organic insulating layer including an organic insulating material (e.g., an acrylic resin, an epoxy resin, a phenolic resin, a polyamide resin, and/or a polyimide resin). Each of the first planarization layer 160 and the second planarization layer 180 may be formed as a single-layer or multi-layer structure.

A light emitting element layer may be disposed on the second planarization layer 180. The light emitting element layer may include pixel electrodes PXE, a common electrode CE, and tandem light emitting elements TLE. The light emitting element layer may further include a first organic layer 211, a first capping layer CAP1, a partition wall BWL, a second organic layer 212, and a second capping layer CAP2 disposed around the tandem light emitting elements TLE.

A pixel electrode layer may be disposed on the second planarization layer 180. The pixel electrode layer may include pixel electrodes PXE (e.g., a first pixel electrode PXE1, a second pixel electrode PXE2, and a third pixel electrode PXE3) of the sub-pixels SPX and a common electrode CE.

Each of the pixel electrodes PXE may be electrically connected to the second source connection electrode PCE2 of each sub-pixel SPX through the contact hole CT (e.g., the first contact hole CT1, the second contact hole CT2, or the third contact hole CT3 in FIG. 6) penetrating through the second planarization layer 180. Each of the pixel electrodes PXE may be electrically connected to the thin film transistor TFT1 through the first source connection electrode PCE1 and the second source connection electrode PCE2.

The pixel electrode layer may include a conductive metal (e.g., molybdenum (Mo), aluminum (Al), chromium (Cr), gold (Au), titanium (Ti), nickel (Ni), neodymium (Nd), and/or copper (Cu), and/or an alloy thereof) and may be formed as a single layer or a multi-layer. For example, each of the pixel electrodes PXE and the common electrode CE may be formed as a single-layer or multi-layer conductive pattern including at least one conductive material. The pixel electrodes PXE and the common electrode CE may be concurrently (e.g., simultaneously) formed and can include the same conductive material.

In one or more embodiments, the pixel electrode layer may include a reflective layer including a metal having high reflectivity. As an example, each of the pixel electrodes PXE and the common electrode CE may include a reflective layer. Accordingly, luminance and light efficiency of the sub-pixels SPX may be improved by reflecting the light directed downward from each of the tandem light emitting elements TLE.

Each tandem light emitting element TLE may be disposed on the pixel electrodes PXE and the common electrode CE. In one or more embodiments, each of the tandem light emitting elements TLE may be a tandem micro LED including an inorganic material (e.g., gallium nitride (GaN)). For example, a length in the first direction DR1, a length in the second direction DR2, and a length in the third direction DR3 of each of the tandem light emitting elements TLE may each be several to several hundreds of μm. As an example, the length in the first direction DR1, the length in the second direction DR2, and the length in the third direction DR3 of each of the tandem light emitting elements TLE may each be 100 μm or less.

The tandem light emitting elements TLE may be grown and formed on a semiconductor substrate such as a silicon substrate and/or a sapphire substrate. The tandem light emitting elements TLE may be transferred directly onto the pixel electrodes PXE and the common electrodes CE on the semiconductor substrate. Alternatively, the tandem light emitting elements TLE may be transferred onto the pixel electrodes PXE and the common electrodes CE by an electrostatic method using an electrostatic head or by a stamping method using an elastic polymer material such as PDMS or silicone as a transfer substrate.

In one or more embodiments, the tandem light emitting element TLE may include a first light emitting element LE1 and a second light emitting element LE2, each including a semiconductor stack. For example, the tandem light emitting element TLE may include a first light emitting element LE1 including a first semiconductor stack STC1, and a second light emitting element LE2 including a second semiconductor stack STC2.

The tandem light emitting element TLE may further include a filling layer FIL (e.g., an insulating layer including a filling material made of an insulating material) disposed between the first light emitting element LE1 and the second light emitting element LE2, a first electrode ET1 electrically connected to the first light emitting element LE1, a second electrode ET2 electrically connected to the second light emitting element LE2, and a connection electrode CNE electrically connecting the first light emitting element LE1 and the second light emitting element LE2. In one or more embodiments, the first light emitting element LE1 and the second light emitting element LE2 may be horizontally coupled with the filling layer FIL interposed therebetween.

In one or more embodiments, the tandem light emitting element TLE may include light extraction patterns LEP formed on a light emitting surface. For example, the tandem light emitting element TLE may include light extraction patterns LEP formed on an upper surface (e.g., an upper surface of the first semiconductor stack STC1, an upper surface of the second semiconductor stack STC2, and an upper surface of the filler layer FIL). The light extraction patterns LEP are formed by imparting surface roughness to the upper surface of the tandem light emitting element TLE and may have a shape and/or size suitable for increasing the light emitting rate of the tandem light emitting element TLE. For example, the upper surface of the tandem light emitting element TLE may be formed to be non-flat so that the upper surface of the tandem light emitting element TLE has a shape suitable for light scattering. Accordingly, the light efficiency of the tandem light emitting element TLE (e.g., the light emitting rate of light generated from the tandem light emitting element TLE) may be increased.

The first light emitting element LE1 may include a first semiconductor stack STC1 and a protective film PRL covering a portion of a lower surface and side surfaces of the first semiconductor stack STC1. The second light emitting element LE2 may include a second semiconductor stack STC2 and a protective film PRL covering a portion of a lower surface and side surfaces of the second semiconductor stack STC2.

Each of the first semiconductor stack STC1 and the second semiconductor stack STC2 may include a first semiconductor layer SEM1, an active layer MQW, and a second semiconductor layer SEM2 sequentially disposed or stacked in the third direction DR3. In one or more embodiments, each of the first semiconductor stack STC1 and the second semiconductor stack STC2 (or the first light emitting element LE1 and the second light emitting element LE2) may optionally include an electrode layer disposed between the first electrode ET1 or the second electrode ET2 and the first semiconductor layer SEM1, an additional semiconductor layer (e.g., an undoped or low-doped semiconductor layer) disposed on the second semiconductor layer SEM2, and/or additional functional layers (e.g., super-lattice layers and electron blocking layers).

The first semiconductor layer SEM1 may include a semiconductor material (e.g., gallium nitride (GaN)) and a first conductive dopant. As an example, the first semiconductor layer SEM1 may be formed as a semiconductor material layer doped with a p-type dopant such as magnesium (Mg), zinc (Zn), calcium (Ca), strontium (Sr), barium (Ba), etc. (e.g., a gallium nitride (p-GaN) layer including a p-type dopant).

The active layer MQW may be disposed on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). As an example, the active layer MQW may include gallium nitride (GaN), indium gallium nitride (InGaN), and/or aluminum gallium nitride (AlGaN). Light may be generated by recombination of electron-hole pairs depending on electric signals applied to the active layer MQW through the first semiconductor layer SEM1 and the second semiconductor layer SEM2.

The active layer MQW may have a single or multi quantum well structure. When the active layer MQW has a multi quantum well structure, the active layer MQW may include well layers and barrier layers that are alternately stacked. In one or more embodiments, each well layer may include InGaN, and each barrier layer may include GaN and/or AlGaN, but the present disclosure is not limited thereto. Alternatively, the active layer MQW may also have a structure in which semiconductor materials having large band gap energy and semiconductor materials having small band gap energy are alternately stacked, and may also include other Group III to Group V semiconductor materials depending on a wavelength band of emitted light.

When the active layer MQW includes indium gallium nitride (InGaN), a color of the emitted light may be changed depending on the content of indium (In). For example, as the content of indium (In) increases, a wavelength band of the light emitted by the active layer MQW may move to a red wavelength band, and as the content of indium (In) decreases, a wavelength band of the light emitted by the active layer MQW may move to a blue wavelength band. For example, when red light, green light, and blue light are emitted from the first tandem light emitting element TLE1, the second tandem light emitting element TLE2, and the third tandem light emitting element TLE3, respectively, the content of indium (In) in the active layer MQW included in the second tandem light emitting element TLE2 may be lower than the content of indium (In) in the active layer MQW included in the first tandem light emitting element TLE1, and may be higher than the content of indium (In) in the active layer MQW included in the third tandem light emitting element TLE3.

The second semiconductor layer SEM2 may be disposed on the active layer MQW. The second semiconductor layer SEM2 may include a semiconductor material (e.g., gallium nitride (GaN)) and a second conductive dopant. As an example, the second semiconductor layer SEM2 may be formed as a semiconductor material layer doped with an n-type dopant such as silicon (Si), germanium (Ge), or tin (Sn) (e.g., a gallium nitride (n-GaN) layer including an n-type dopant).

The protective film PRL may be disposed on a portion of a lower surface and side surfaces (e.g., outer peripheral surfaces) of each of the first semiconductor stack STC1 and the second semiconductor stack STC2. The protective film PRL is intended to protect the side surfaces of each of the first semiconductor stack STC1 and the second semiconductor stack STC2, and may include an inorganic insulating material (e.g., silicon nitride (SiNx), silicon nitride oxide (SiON), silicon oxide (SiOx), titanium oxide (TiOx), and/or aluminum oxide (AlOx)). At least one opening may be formed in the protective film PRL to expose a portion of each of the first semiconductor layer SEM1 and the second semiconductor layer SEM2 included in each of the first semiconductor stack STC1 and the second semiconductor stack STC2.

At a portion where the first semiconductor layer SEM1 of the first semiconductor stack STC1 is exposed, the first electrode ET1 of the tandem light emitting element TLE and the first semiconductor layer SEM1 of the first semiconductor stack STC1 (or a conductive layer connected to the first semiconductor layer SEM1) may be in contact with each other. Accordingly, the first semiconductor layer SEM1 of the first semiconductor stack STC1 may be electrically connected to the first electrode ET1 of the tandem light emitting element TLE.

At a portion where the second semiconductor layer SEM2 of the first semiconductor stack STC1 is exposed, the connection electrode CNE of the tandem light emitting element TLE and the second semiconductor layer SEM2 of the first semiconductor stack STC1 may be in contact with each other. Accordingly, the second semiconductor layer SEM2 of the first semiconductor stack STC1 may be electrically connected to the connection electrode CNE of the tandem light emitting element TLE.

At a portion where the first semiconductor layer SEM1 of the second semiconductor stack STC2 is exposed, the connection electrode CNE of the tandem light emitting element TLE and the first semiconductor layer SEM1 of the second semiconductor stack STC2 (or a conductive layer connected to the first semiconductor layer SEM1) may be in contact with each other. Accordingly, the first semiconductor layer SEM1 of the second semiconductor stack STC2 may be electrically connected to the connection electrode CNE of the tandem light emitting element TLE.

At a portion where the second semiconductor layer SEM2 of the second semiconductor stack STC2 is exposed, the second electrode ET2 of the tandem light emitting element TLE and the second semiconductor layer SEM2 of the second semiconductor stack STC2 may be in contact with each other. Accordingly, the second semiconductor layer SEM2 of the second semiconductor stack STC2 may be electrically connected to the second electrode ET2 of the tandem light emitting element TLE.

The first electrode ET1 of the tandem light emitting element TLE may be disposed on a lower surface of the first light emitting element LE1. As an example, the first electrode ET1 of the tandem light emitting element TLE may be disposed on a portion of a lower surface of the first semiconductor stack STC1.

The first electrode ET1 of the tandem light emitting element TLE may be bonded onto the pixel electrode PXE. For example, the first electrode ET1 of the first tandem light emitting element TLE1 may be bonded onto the first pixel electrode PXE1. Similarly, the first electrode ET1 of the second tandem light emitting element TLE2 may be bonded onto the second pixel electrode PXE2, and the first electrode ET1 of the third tandem light emitting element TLE3 may be bonded onto the third pixel electrode PXE3.

The second electrode ET2 of the tandem light emitting element TLE may be disposed on a lower surface of the second light emitting element LE2. As an example, the second electrode ET2 of the tandem light emitting element TLE may be disposed on a portion of a lower surface of the second semiconductor stack STC2 (e.g., a portion of a lower surface of the second semiconductor layer SEM2).

The second electrode ET2 of the tandem light emitting element TLE may be bonded onto the common electrode CE. For example, the second electrode ET2 of the first tandem light emitting element TLE1 may be bonded onto a portion of the common electrode CE disposed in the first sub-pixel area. Similarly, the second electrode ET2 of the second tandem light emitting element TLE2 may be bonded onto a portion of the common electrode CE disposed in the second sub-pixel area, and the second electrode ET2 of the third tandem light emitting element TLE3 may be bonded onto a portion of the common electrode CE disposed in the third sub-pixel area.

Each of the first electrode ET1 and the second electrode ET2 of the tandem light emitting element TLE may include a conductive material and may be formed as a single layer or a multi-layer. The first electrode ET1 and the second electrode ET2 of the tandem light emitting element TLE may be bonded onto the pixel electrode PXE and the common electrode CE, respectively, by a bonding method using heat and/or pressure (e.g., eutectic bonding), or a bonding method using a medium layer including a conductive material (e.g., an anisotropic conductive film including conductive balls). The first electrode ET1 and the second electrode ET2 of the tandem light emitting element TLE may include a conductive material suitable for each bonding method. An example, the tandem light emitting element TLE may be bonded onto the pixel electrode PXE and the common electrode CE by a eutectic bonding method, and the first electrode ET1 and the second electrode ET2 of the tandem light emitting element TLE may include a metal that is suitable for eutectic bonding and has excellent conductivity. In one or more embodiments, the first electrode ET1 and the second electrode ET2 of the tandem light emitting element TLE may include the same conductive material.

In one or more embodiments, a first bonding layer BDL1 may be disposed between the first electrode ET1 of the tandem light emitting element TLE and each pixel electrode PXE, and a second bonding layer BDL2 may be disposed between the second electrode ET2 of the tandem light emitting element TLE and the common electrode CE. For example, the first electrode ET1 of the tandem light emitting element TLE may be bonded to the pixel electrode PXE via the first bonding layer BDL1, and the second electrode ET2 of the tandem light emitting element TLE may be bonded to the common electrode CE via the second bonding layer BDL2.

The first bonding layer BDL1 and the second bonding layer BDL2 may include a material suitable for stably bonding the tandem light emitting element TLE onto each pixel electrode PXE and the common electrode CE. For example, when bonding the tandem light emitting element TLE onto each pixel electrode PXE and the common electrode CE by the eutectic bonding, the first bonding layer BDL1 and the second bonding layer BDL2 may include a metal such as a eutectic alloy. In one or more embodiments, the first bonding layer BDL1 and the second bonding layer BDL2 may include the same conductive material.

The connection electrode CNE may connect the first light emitting element LE1 and the second light emitting element LE2 in series. The connection electrode CNE may include a conductive material suitable for stably connecting the first light emitting element LE1 and the second light emitting element LE2. As an example, the connection electrode CNE may include a transparent conductive oxide (TCO), such as indium tin oxide (ITO) and/or indium zinc oxide (IZO), or may include a metal or a metal alloy.

The filling layer FIL may fill a space between the first light emitting element LE1 and the second light emitting element LE2. The filling layer FIL may include an insulating material and may also be referred to as an “insulating layer”. In one or more embodiments, the filling layer FIL may be substantially transparent. Accordingly, the light generated from the tandem light emitting element TLE may be prevented from being absorbed and extinguished in the filling layer FIL.

A first organic layer 211 may be disposed on and/or around the pixel electrodes PXE, the common electrode CE, and the tandem light emitting elements TLE.

The first organic layer 211 may be disposed around the tandem light emitting elements TLE to be around (e.g., to surround) the tandem light emitting elements TLE. As an example, the first organic layer 211 may be disposed on at least a portion of the pixel electrodes PXE, the common electrode CE, and the tandem light emitting elements TLE, and may fill a space around the tandem light emitting elements TLE. In one or more embodiments, the first organic layer 211 may be formed to have a height (e.g., in the third direction DR3) lower than a height (e.g., in the third direction DR3) of the tandem light emitting elements TLE and may be around (e.g., may surround) a portion of the side surface of the tandem light emitting elements TLE.

The first organic layer 211 may be formed as an organic film made of an acryl resin, an epoxy resin, a phenolic resin, a polyamide resin, and/or a polyimide resin. The first organic layer 211 may alleviate a step difference caused by the tandem light emitting elements TLE.

A first capping layer CAP1 may be disposed on the tandem light emitting elements TLE and the first organic layer 211. The first capping layer CAP1 may include a material suitable for protecting the tandem light emitting elements TLE, for example, an inorganic insulating material.

A partition wall BWL (e.g., a bank structure) and a second organic layer 212 may be disposed on the first capping layer CAP1.

The partition wall BWL may be around (e.g., may surround) the light emitting area in which each tandem light emitting element TLE is disposed. For example, the partition wall BWL may be around (e.g., may surround) each tandem light emitting element TLE at a location spaced from each tandem light emitting element TLE. The partition wall BWL may define a light transmitting area through which the light emitted from each tandem light emitting element TLE may transmit, for example, a light emitting area of each sub-pixel SPX. For example, the partition wall BWL may be disposed to be around (e.g., to surround) each light emitting area including the area where each tandem light emitting element TLE is disposed and its surroundings, and may be opened to correspond to the light emitting area.

The partition wall BWL may include a bank BNK defining a shape of the partition wall BWL and a first insulating layer INS1 covering the bank BNK. In one or more embodiments, the partition wall BWL may further include a reflective film RF disposed on the first insulating layer INS1, and a second insulating layer INS2 covering the reflective film RF.

The bank BNK may include an organic material. As an example, the bank BNK may be formed as an organic film including an organic material such as an acryl resin, an epoxy resin, a phenolic resin, a polyamide resin, and/or a polyimide resin, but is not limited thereto.

The first insulating layer INS1 may include an inorganic material. As an example, the first insulating layer INS1 may include an inorganic material such as silicon nitride (SiNₓ), silicon oxide nitride (SiON), silicon oxide (SiOₓ), titanium oxide (TiOₓ), and/or aluminum oxide (AlOₓ).

The reflective film RF may be disposed on a side surface of the bank BNK. In one or more embodiments, the reflective film RF may also be disposed on an upper surface of the bank BNK. As an example, the reflective film RF may entirely cover the bank BNK.

The reflective film RF may face the side surface of the tandem light emitting element TLE. The reflective film RF facing the side surface of the tandem light emitting element TLE may include a case where the reflective film RF horizontally faces at least a portion of the side surface of the tandem light emitting element TLE at the same height, and a case where the reflective film RF is disposed at a position and/or height where the light emitted laterally from the tandem light emitting element TLE may reach.

The reflective film RF may include a material having high light reflectivity, for example, a metal such as aluminum (Al). Alternatively, the reflective film RF may also be formed as a distributed Bragg reflector including inorganic films having different refractive indices and alternately disposed (e.g., silicon nitride (SiNₓ), silicon oxynitride (SiON), silicon oxide (SiOₓ), titanium oxide (TiOₓ), and/or aluminum oxide (AlOₓ)). By reflecting the light that has traveled in the lateral direction of the tandem light emitting element TLE by the reflective film RF, the light emitting rate of the sub-pixel SPX may be increased.

The second insulating layer INS2 may include an inorganic material. As an example, the second insulating layer INS2 may include an inorganic material such as silicon nitride (SiNₓ), silicon oxide nitride (SiON), silicon oxide (SiOₓ), titanium oxide (TiOₓ), and/or aluminum oxide (AlOₓ).

The second organic layer 212 may be filled between the tandem light emitting elements TLE and the partition wall BWL. In one or more embodiments, the second organic layer 212 may be formed to have a height higher than the height of the tandem light emitting elements TLE and the partition wall BWL to entirely cover the tandem light emitting elements TLE and the partition wall BWL.

The second organic layer 212 may include an organic material. As an example, the second organic layer 212 may be formed as an organic film including an organic material such as an acryl resin, an epoxy resin, a phenolic resin, a polyamide resin, and/or a polyimide resin. The second organic layer 212 can alleviate or planarize the step difference caused by the tandem light emitting elements TLE and the partition wall BWL.

In one or more embodiments, the tandem light emitting elements TLE may emit light of a color corresponding to the emission color of each sub-pixel SPX, and the second organic layer 212 may transmit the light emitted from the tandem light emitting elements TLE of the sub-pixels SPX. For example, the second organic layer 212 may transmit light of a first color, light of a second color, and light of a third color emitted from the first tandem light emitting element TLE1, the second tandem light emitting element TLE2, and the third tandem light emitting element TLE3. When the sub-pixels SPX include the tandem light emitting elements TLE that emit light corresponding to each emission color, the light emitted from the tandem light emitting elements TLE may be more efficiently utilized. For example, a decrease in an optical efficiency of the sub-pixels SPX due to light conversion may be reduced or prevented. In addition, color purity of the light emitted from the sub-pixels SPX may be increased.

In one or more embodiments, when a tandem light emitting element TLE of at least one sub-pixel SPX emits light of a color different from the emission color of the corresponding sub-pixel SPX, a light conversion layer may be disposed on the tandem light emitting element TLE. As an example, the partition wall BWL having a height higher than the height of the tandem light emitting elements TLE may be formed to partition a light transmitting area of each sub-pixel SPX, and the light conversion layer may be disposed within each light transmitting area partitioned by the partition wall BWL. The light conversion layer may include a light transmitting base resin and wavelength conversion particles (e.g., quantum dots, quantum rods, fluorescent materials, and/or phosphorescent materials) dispersed within the base resin, and convert light emitted from a tandem light emitting element TLE of the corresponding sub-pixel SPX into light of a different color. As an example, when the first tandem light emitting element TLE1 emits blue light and the first sub-pixel SPX1 is a red sub-pixel that emits red light, a light conversion layer that converts the blue light into the red light may be disposed on the first tandem light emitting element TLE1. When the sub-pixels SPX include the tandem light emitting elements TLE that emit light of the same color, the manufacturing efficiency of the display panel 100 may be increased.

A second capping layer CAP2 may be disposed on the second organic layer 212. The second capping layer CAP2 may include an inorganic material such as silicon nitride (SiNₓ), silicon oxide nitride (SiON), silicon oxide (SiOₓ), titanium oxide (TiOₓ), and/or aluminum oxide (AlOₓ). The second capping layer CAP2 may also be omitted.

Color filters of the sub-pixels SPX may be disposed on the second capping layer CAP2 (or the second organic layer 212). A color filter that selectively transmits light of a color (or wavelength) corresponding to the emission color of the sub-pixel SPX may be disposed in the light emitting area of each sub-pixel SPX. As an example, a first color filter CF1 that selectively transmits light of a first color may be disposed in the light emitting area of the first sub-pixel SPX1. Similarly, a second color filter CF2 that selectively transmits light of a second color may be disposed in the light emitting area of the second sub-pixel SPX2, and a third color filter CF3 that selectively transmits light of a third color may be disposed in the light emitting area of the third sub-pixel SPX3.

In one or more embodiments, the color filters of the sub-pixels SPX may be disposed to overlap each other in the non-light emitting area to form a light blocking pattern. As an example, the first color filter CF1, the second color filter CF2, and the third color filter CF3, which are respectively disposed on the tandem light emitting elements TLE of the first sub-pixel SPX1, the second sub-pixel SPX2, and the third sub-pixel SPX3, may overlap each other on the partition wall BWL.

An overcoat layer 213 may be disposed on the color filters. In one or more embodiments, the overcoat layer 213 may include a light transmitting organic material, and an upper surface of the overcoat layer 213 may be substantially flat. As an example, the overcoat layer 213 may include an acrylic resin, an epoxy resin, a phenolic resin, a polyamide resin, and/or a polyimide resin. The overcoat layer 213 may protect the color filters and help ensure uniform light transmission.

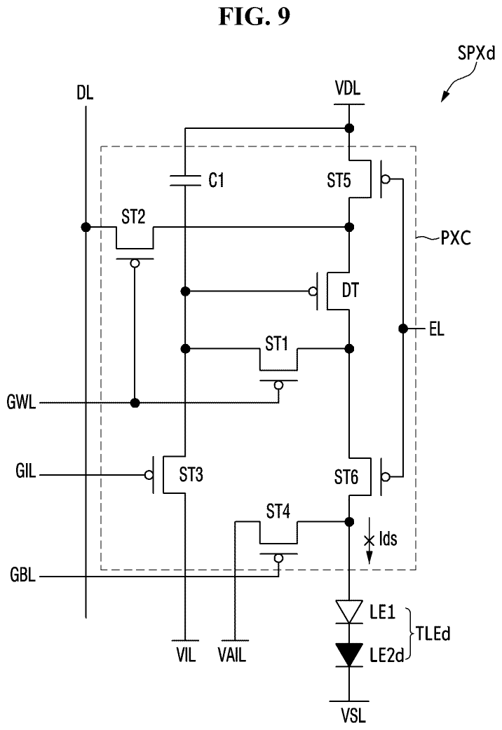

FIG. 9 is an equivalent circuit diagram illustrating a sub-pixel including a defective tandem light emitting element. For example, FIG. 9 illustrates a sub-pixel SPXd that includes a defective tandem light emitting element TLEd in which a second light emitting element LE2d is defective.

In FIG. 9 and the following description, “second light emitting element LE2d” may refer to a second light emitting element LE2 that has a defect among the second light emitting elements LE2 using a distinct reference symbol, and “defective tandem light emitting element TLEd” or “tandem light emitting element TLEd” may refer to a tandem light emitting element TLE that has a defect among the tandem light emitting elements TLE using a distinct reference symbol. In addition, “sub-pixel SPXd” may refer to a sub-pixel SPX that does not normally emit light due to the defective tandem light emitting element TLEd among the sub-pixels SPX using a distinct reference symbol. However, the second light emitting element LE2d, the tandem light emitting element (or the defective tandem light emitting element) TLEd, and the sub-pixel SPXd may also be collectively referred to as the second light emitting element LE2, the tandem light emitting element TLE, and the sub-pixel SPX, respectively.

Referring to FIG. 9 in addition to FIGS. 1-8, because the first light emitting element LE1 and the second light emitting element LE2 of the tandem light emitting element TLE are connected in series, the tandem light emitting element TLE may become a defective tandem light emitting element TLEd, when a defect occurs in at least one of the first light emitting element LE1 or the second light emitting element LE2. Even if a driving signal is applied to a sub-pixel SPX including the defective tandem light emitting element TLEd, the sub-pixel SPX may not emit light.

For example, as illustrated in FIG. 9, when the second light emitting element LE2d is defective, a conductive path through which a driving current Ids may flow in the sub-pixel SPX may be blocked. In addition, when the first light emitting element LE1 is defective or both the first light emitting element LE1 and the second light emitting element LE2d are defective, the conductive path through which the driving current Ids may flow in the sub-pixel SPX may be blocked.

Therefore, even when only one of the first light emitting element LE1 or the second light emitting element LE2 or LE2d is defective, both the first light emitting element LE1 and the second light emitting element LE2 or LE2d included in the tandem light emitting element TLEd may not emit light. The sub-pixel SPX including the defective tandem light emitting element TLEd may not emit light and may appear as a dark spot.

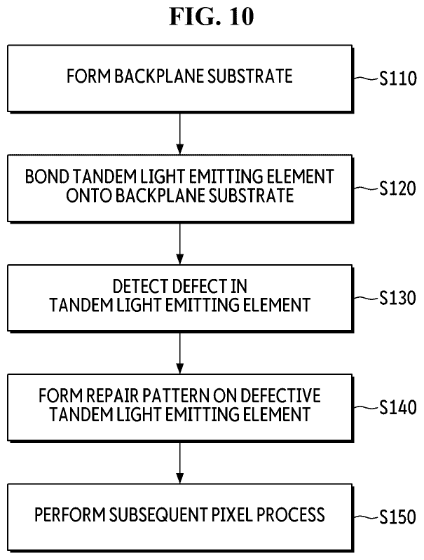

FIG. 10 is a flowchart illustrating a method for manufacturing a display device according to one or more embodiments. For example, FIG. 10 is a flowchart schematically illustrating a method for manufacturing the display panel 100 included in the display device 1 according to one or more embodiments, and schematically illustrates a method for manufacturing the display panel 100, including a step of repairing a defect in the sub-pixel (SPXd in FIG. 9) due to a defect in the second light emitting element (LE2d in FIG. 9).

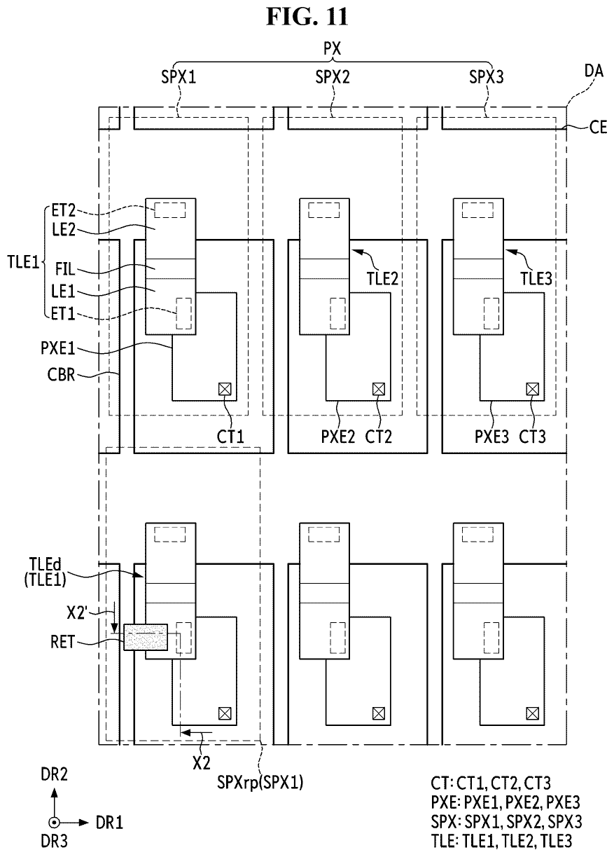

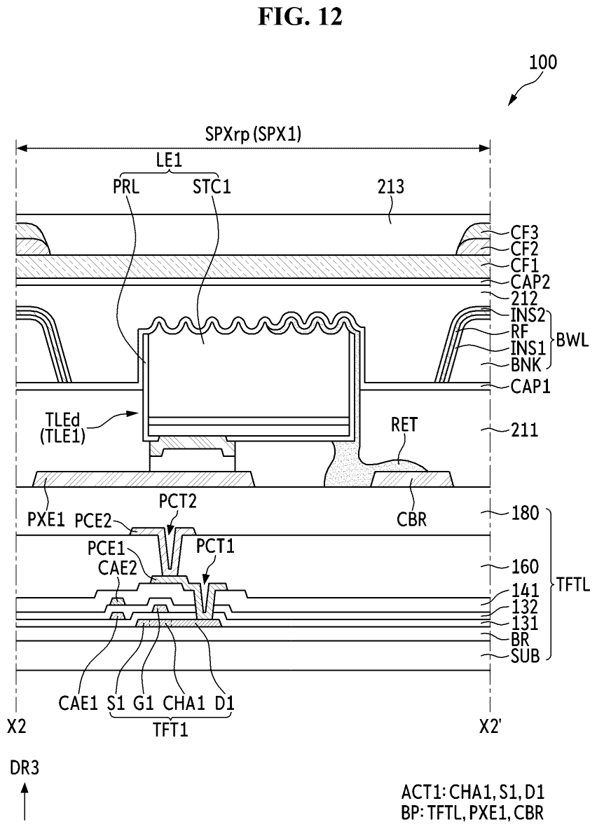

The method for manufacturing the display panel 100 according to one or more embodiments may include a step of forming a repair pattern RET as illustrated in FIGS. 11 and 12. Accordingly, the method for manufacturing the display panel 100 according to one or more embodiments will be described with reference to FIGS. 11 and 12.

FIG. 11 is a plan view illustrating a display area of a display panel according to one or more embodiments. Compared with FIGS. 5 and 6, FIG. 11 illustrates a portion of a display area DA in which a sub-pixel SPXrp including a repair pattern RET is disposed.

FIG. 12 is a cross-sectional view illustrating a display area of a display panel according to one or more embodiments. For example, FIG. 12 illustrates an example of a cross-section of a sub-pixel SPXrp including a repair pattern RET (e.g., a first sub-pixel SPX1 including a repair pattern RET) corresponding to line X2-X2′ of FIG. 11.

In FIGS. 11 and 12 and the following description, “sub-pixel SPXrp” may refer to a sub-pixel SPX repaired by a repair pattern RET among the sub-pixels SPX using a distinct reference symbol. However, the sub-pixel SPXrp may also be collectively referred to as the sub-pixel SPX.

Referring to FIGS. 10-12 in addition to FIG. 1-9, in order to manufacture a display panel 100 of a display device 1 according to one or more embodiments, a backplane substrate BP may first be formed (S110).

For example, a thin film transistor TFT1, etc. may be formed on a substrate SUB to form a thin film transistor layer TFTL of FIGS. 7 and 12, and pixel electrodes PXE and a common electrode CE may be formed on the thin film transistor layer TFTL. The common electrode CE may include a branch CBR. Accordingly, the backplane substrate BP including the thin film transistor layer TFTL, the pixel electrodes PXE, and the common electrode CE may be formed.

Thereafter, a tandem light emitting element TLE may be bonded onto the backplane substrate BP (S120).

For example, as illustrated in FIG. 5-6, the tandem light emitting element TLE may be bonded onto the pixel electrode PXE and the common electrode CE of each sub-pixel SPX. In one or more embodiments, a first electrode ET1 and a second electrode ET2 of the tandem light emitting element TLE may be bonded to the pixel electrode PXE and the common electrode CE, respectively, by a eutectic bonding method, but the bonding (or arrangement) method of the tandem light emitting element TLE is not limited thereto.

Thereafter, a defect in the tandem light emitting element TLE may be detected (S130).

For example, after bonding the tandem light emitting element TLE onto the pixel electrode PXE and the common electrode CE of each of the sub-pixels SPX, before forming the first organic layer 211 and the first capping layer CAP1 of FIGS. 7 and 12, an electroluminescence (EL) test and a photoluminescence (PL) test may be performed. Specifically, the EL test that lights up the tandem light emitting element TLE by applying a driving voltage to the pixel electrode PXE and the common electrode CE of each sub-pixel SPX and tests light emitting characteristics of the tandem light emitting element TLE may be performed. A tandem light emitting element TLE that abnormally emit light or does not emit light at all may be detected by the EL test. The tandem light emitting element TLE that does not normally emit light during the EL test step may be a defective tandem light emitting element TLEd that is not properly bonded or has a defect in the element itself.

Thereafter, a PL test that tests light emitting characteristics by irradiating an external light source on the tandem light emitting element TLE that does not normally emit light in the EL test may be performed. The defective tandem light emitting element TLEd may be detected by the PL test and the type of defect occurring in the defective tandem light emitting element TLEd may be determined.

For example, when neither the first light emitting element LE1 nor the second light emitting element LE2d emits light In the PL test, the defect may be determined to be a type 1 defect in which both the first light emitting element LE1 and the second light emitting element LE2d are defective. In the PL test, when the first light emitting element LE1 does not emit light and only the second light emitting element LE2 emits light, the defect may be determined to be a type 2 defect in which only the first light emitting element LE1 is defective, and when only the first light emitting element LE1 emits light and the second light emitting element LE2d does not emit light, the defect may be determined to be a type 3 defect in which only the second light emitting element LE2d is defective.

Thereafter, a repair pattern RET may be formed on the defective tandem light emitting element TLEd (S140).

For example, a repair pattern RET may be formed on the defective tandem light emitting element TLEd determined to be the type 3 defect, as illustrated in FIG. 11. For example, when the first tandem light emitting element TLE1 bonded onto the first pixel electrode PXE1 and the common electrode CE of one first sub-pixel SPX1 illustrated in FIG. 11 is determined to be a defective tandem light emitting element TLEd including the type 3 defect, a repair pattern RET may be formed on the first light emitting element LE1 of the defective tandem light emitting element TLEd and the branch CBR of the common electrode CE adjacent thereto. The repair pattern RET may include a conductive material.

In one or more embodiments, the repair pattern RET may be directly formed on the upper surface of the first light emitting element LE1 (e.g., the upper surface of the second semiconductor layer SEM2 included in the first semiconductor stack STC1 of FIG. 8) and a portion of the branch CBR of the common electrode CE, as illustrated in FIG. 12. The repair pattern RET may be spaced from the first electrode ET1 and the pixel electrode PXE of the defective tandem light emitting element TLEd, thereby preventing a short circuit defect.

The first light emitting element LE1 of the defective tandem light emitting element TLEd may be electrically connected to the common electrode CE by the repair pattern RET. For example, the second semiconductor layer SEM2 included in the first semiconductor stack STC1 of the defective tandem light emitting element TLEd may be electrically connected to the branch CBR of the common electrode CE through the repair pattern RET.

In one or more embodiments, the repair pattern RET may be formed by applying a conductive dot (e.g., a repair dot). For example, the repair pattern RET may be formed by applying the conductive dot on an area where the first light emitting element LE1 of the defective tandem light emitting element TLEd and the branch CBR of the common electrode CE is disposed and then curing the conductive dot, by dispensing silver (Ag) or other conductive materials (e.g., metal paste or conductive ink) in the form of a dot (or dots). As an example, the repair pattern RET may be made of or include the conductive dot. In one or more embodiments, the conductive dot (e.g., a silver (Ag) dot) may be dropped onto a portion of the defective tandem light emitting element TLEd by a non-contact method such as jet dispensing, but the method of forming the repair pattern RET is not limited thereto.

It is illustrated in FIG. 11 that the repair pattern RET has a square shape, but the shape of the repair pattern RET may vary. In addition, the size, thickness, and/or material of the repair pattern RET may be adjusted or changed so that light generated from the first light emitting element LE1 may be appropriately emitted.

In one or more embodiments, for defects other than the type 3 defect (e.g., type 1 or type 2 defect in which at least the first light emitting element LE1 is defective, or bonding defect), the defects may be repaired in other methods. As an example, a defective tandem light emitting element TLE may be removed using a laser, and the defect may be repaired by bonding a good tandem light emitting element TLE to the portion from which the defective tandem light emitting element TLE was removed.

After the repair pattern RET, etc., is formed, an additional EL test may be performed to confirm whether the tandem light emitting element TLE or TLEd of each sub-pixel SPX normally emits light. When the tandem light emitting elements TLE or TLEd of the sub-pixels SPX normally emit light, the repair process may be completed.

Thereafter, subsequent pixel processes may be performed (S150).

For example, the first organic layer 211, the first capping layer CAP1, the partition wall BWL, the second organic layer 212, and the second capping layer CAP2 of FIGS. 7 and 12 may be formed on the backplane substrate BP and the tandem light emitting elements TLE or TLEd. Accordingly, a light emitting element layer including the tandem light emitting elements TLE and TLEd may be formed on the backplane substrate BP.

In one or more embodiments, when the display panel 100 further includes the first, second, and third color filters CF1, CF2, and CF3 of FIGS. 7 and 12, the first, second, and third color filters CF1, CF2, and CF3 and an overcoat layer 213 may be formed on the second capping layer CAP2. Accordingly, the display panel 100 according to one or more embodiments may be formed.

Referring to FIGS. 11 and 12, the display panel 100 according to one or more embodiments may include sub-pixels SPX disposed in the display area DA. In one or more embodiments, at least one of the sub-pixels SPX may include a repair pattern RET, and other sub-pixels SPX may not include the repair pattern RET.

For example, a sub-pixel SPX including a tandem light emitting element TLE in which a first light emitting element LE1 and a second light emitting element LE2 normally emit light may not include the repair pattern RET, and as illustrated in FIG. 7, the first capping layer CAP1 may be directly disposed on the tandem light emitting element TLE. On the other hand, a sub-pixel SPX including a tandem light emitting element TLEd in which the second light emitting element LE2 does not emit light may include the repair pattern RET disposed on the first light emitting element LE1, and as illustrated in FIG. 12, the repair pattern RET and the first capping layer CAP1 may be sequentially disposed on the tandem light emitting element TLEd.

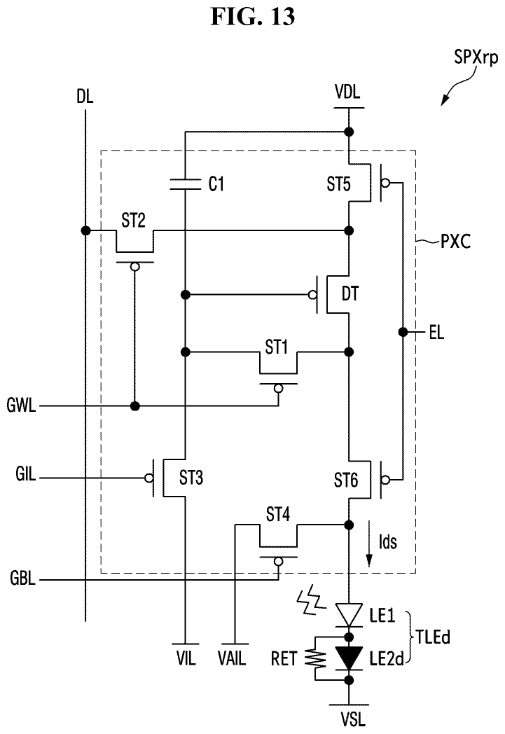

FIG. 13 is an equivalent circuit diagram illustrating a repaired sub-pixel according to one or more embodiments. For example, FIG. 13 illustrates a sub-pixel SPXrp that includes a tandem light emitting element TLEd in which the second light emitting element LE2d is defective, but has been repaired by the repair pattern RET. Compared with FIG. 9, FIG. 13 illustrates an equivalent circuit diagram of a sub-pixel SPXrp including a repair pattern RET.

Referring to FIG. 13 in addition to FIGS. 1-12, a conductive path through which a driving current Ids may flow may be formed by the repair pattern RET in the sub-pixel SPXrp including the repair pattern RET. In the tandem light emitting element TLEd of the sub-pixel SPXrp including the repair pattern RET, only the first light emitting element LE1 may emit light in response to the driving signal applied to the sub-pixel SPXrp, and the second light emitting element LE2d may not emit light.

For example, the driving current Ids supplied from the pixel circuit PXC to the first light emitting element LE1 may flow to the second power line VSL via the first light emitting element LE1 and the repair pattern RET. Accordingly, the first light emitting element LE1 may emit light with luminance corresponding to the driving current Ids. The repair pattern RET may serve as a connection pattern or line that forms a bypass path through which the driving current Ids may flow without passing through the second light emitting element LE2d, and may act as a resistance component.

The sub-pixel SPXrp repaired by the repair pattern RET may emit light with luminance corresponding to emission luminance of the first light emitting element LE1. In one or more embodiments, the luminance of the repaired sub-pixel SPXrp may be adjusted or compensated by adjusting the driving current Ids of the repaired sub-pixel SPXrp. As an example, the luminance of the repaired sub-pixel SPXrp may be improved by adjusting a data voltage supplied to the repaired sub-pixel SPXrp so as to compensate for a decrease in luminance due to non-emission of the second light emitting element LE2d.

According to the display device 1 and the method for manufacturing the same according to one or more embodiments, a defect in the sub-pixel SPX caused by the tandem light emitting element TLE may be efficiently repaired. For example, the defect in the sub-pixel SPX caused by the tandem light emitting element TLE may be quickly and/or easily repaired by forming the repair pattern RET such as a conductive dot to electrically connect the first light emitting element LE1 of the tandem light emitting element TLE to the common electrode CE without removing the tandem light emitting element TLE in which only the second light emitting element LE2 is defective (e.g., the defective tandem light emitting element TLEd in FIG. 9 and FIGS. 11-13). In the repaired sub-pixel (e.g., the sub-pixel SPXrp including the repair pattern RET in FIGS. 11 to 13), the first light emitting element LE1 may emit light. Accordingly, the time and cost required for the repair process performed after bonding of the tandem light emitting element TLE (e.g., the time required to replace the tandem light emitting element TLE and the cost of purchasing a replacement tandem light emitting element TLE) may be reduced. Therefore, according to one or more embodiments, it is possible to increase the manufacturing efficiency of the display device 1 (or an electronic device including the display panel 100 according to one or more embodiments) and reduce the manufacturing cost thereof.

The display device 1 according to at least one of the embodiments described above may be applied to various electronic devices. An electronic device according to one or more embodiments may include the display device 1 (or the display module including the display panel 100 according to at least one embodiment), and may further include a module or device having additional functions in addition to the display device 1.

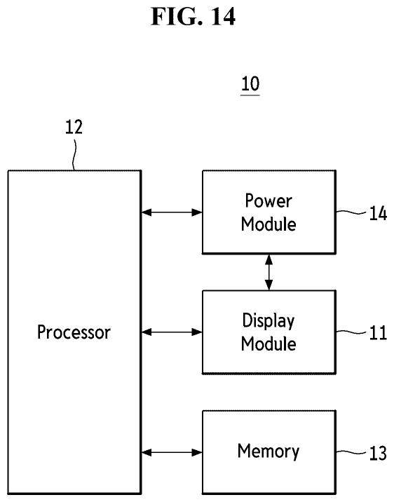

FIG. 14 is a block diagram of an electronic device according to one or more embodiments.

Referring to FIG. 14, an electronic device 10 according to one or more embodiments may include a display module 11, a processor 12, a memory 13, and a power module 14.

The electronic device 10 may output various information in the form of an image through the display module 11. For example, when the processor 12 executes an application stored in the memory 13, image information provided by the application may be provided to the user through the display module 11.

The display module 11 may include a display panel 100 for displaying an image. As an example, the display module 11 may include the display panel 100 according to at least one of the embodiments described above.

The processor 12 may include at least one of a central processing unit (CPU), an application processor (AP), a graphic processing unit (GPU), a communication processor (CP), an image signal processor (ISP), and/or a controller.

Data information necessary for an operation of the processor 12 or the display module 11 may be stored in the memory 13. For example, the memory 13 may store image data signals and/or input control signals.

The processor 12 may control the display module 11 using the information stored in the memory 13. The processor 12 may transmit the image data signals and/or input control signals stored in the memory 13 to the display module 11. For example, when the processor 12 executes an application stored in the memory 13, the image data signals and/or input control signals may be transmitted to the display module 11, and the display module 11 may process the provided signals and output image information through a display screen.

The power module 14 may include a power supply module, such as a power adapter and/or a battery device, and a power conversion module that converts power supplied by the power supply module to generate power required for an operation of the electronic device 10.

At least one of the components of the electronic device 10 described above may be included in the display device 1 according to the embodiments described above. In addition, some of the individual modules functionally included within one module may be included within the display device 1, while others may be provided separately from the display device 1. For example, the display device 1 includes the display module 11, and the processor 12, the memory 13, and the power module 14 may be provided in the form of other devices within the electronic device 10 other than the display device 1.

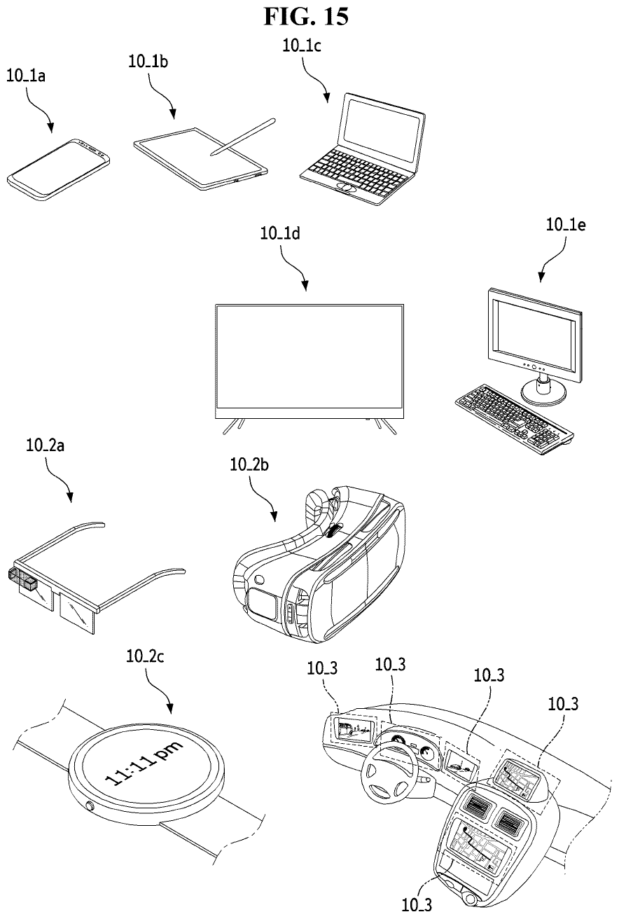

FIG. 15 illustrates schematic diagrams of electronic devices according to various embodiments.

Referring to FIG. 15, various electronic devices to which the display device 1 according to one or more embodiments is applied may include not only an image display electronic device such as a smart phone 10_1a, a tablet PC 10_1b, a laptop 10_1c, a TV 10_1d, and a desk monitor 10_1e, but also a wearable electronic device including a display module such as a smart glasses 10_2a, a head mounted display 10_2b, a smart watch 10_2c, and/or the like, and a vehicle electronic device 10_3 including a display module such as a Center Information Display (CID), a room mirror display, etc., disposed on a vehicle's instrument panel, center fascia, and/or dashboard.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
sub-pixels in a display area,
wherein each of the sub-pixels comprises:
a pixel electrode on a substrate;
a common electrode spaced from the pixel electrode on the substrate and comprising a branch extending to a periphery of the pixel electrode; and
a tandem light emitting element on the pixel electrode and the common electrode, the tandem light emitting element comprising a first electrode bonded to the pixel electrode, a second electrode bonded to the common electrode, a first light emitting element on the first electrode, and a second light emitting element on the second electrode, and
wherein at least one sub-pixel of the sub-pixels comprises a repair pattern on the first light emitting element and the branch of the common electrode, the repair pattern electrically connecting the first light emitting element and the common electrode.

2. The display device of claim 1, wherein in the tandem light emitting element of the at least one sub-pixel, the first light emitting element is configured to emit light in response to a driving signal applied to the at least one sub-pixel, and the second light emitting element does not emit light.

3. The display device of claim 1, wherein another sub-pixel from among the sub-pixels do not include the repair pattern, and
wherein the first light emitting element of the tandem light emitting element in the another sub-pixel is electrically connected to the common electrode via the second light emitting element of the tandem light emitting element.

4. The display device of claim 3, wherein in the tandem light emitting element of the another sub-pixel, the first light emitting element and the second light emitting element are configured to concurrently emit light in response to a driving signal applied to the another sub-pixel.

5. The display device of claim 1, wherein a portion of a lower surface of the first light emitting element is located in an area overlapping the pixel electrode, and
wherein another portion of the lower surface of the first light emitting element is located in an area between the branch of the common electrode and the pixel electrode.

6. The display device of claim 5, wherein the repair pattern comprises a conductive dot covering a portion of an upper surface and a portion of a side surface of the first light emitting element of the tandem light emitting element of the at least one sub-pixel, and a portion of the branch.

7. The display device of claim 5, wherein the first electrode is on a portion of the lower surface of the first light emitting element, and
wherein the repair pattern is spaced from the first electrode of the tandem light emitting element of the at least one sub-pixel.

8. The display device of claim 1, wherein the tandem light emitting element further comprises a connection electrode that connects the first light emitting element and the second light emitting element in series.

9. The display device of claim 1, wherein the tandem light emitting element further comprises a filling layer located between the first light emitting element and the second light emitting element, and
wherein the first light emitting element and the second light emitting element are horizontally coupled with the filling layer interposed therebetween.

10. The display device of claim 1, wherein each of the first light emitting element and the second light emitting element comprises a first semiconductor layer comprising a first conductive dopant, an active layer on the first semiconductor layer, and a second semiconductor layer on the active layer and comprising a second conductive dopant,
wherein the first electrode is electrically connected to the first semiconductor layer of the first light emitting element, and
wherein the second electrode is electrically connected to the second semiconductor layer of the second light emitting element.

11. The display device of claim 10, wherein the repair pattern is on the second semiconductor layer of the first light emitting element.

12. An electronic device comprising:
a display module comprising a display panel comprising sub-pixels; and
a processor configured to transmit an image data signal to the display module,
wherein each of the sub-pixels comprises:
a pixel electrode on a substrate;
a common electrode spaced from the pixel electrode on the substrate and comprising a branch extending to a periphery of the pixel electrode; and
a tandem light emitting element on the pixel electrode and the common electrode, the tandem light emitting element comprising a first electrode bonded to the pixel electrode, a second electrode bonded to the common electrode, a first light emitting element on the first electrode, and a second light emitting element on the second electrode, and
at least one sub-pixel of the sub-pixels comprises a repair pattern on the first light emitting element and the branch of the common electrode, the repair pattern electrically connecting the first light emitting element and the common electrode.

13. The electronic device of claim 12, wherein in the tandem light emitting element of the at least one sub-pixel, the first light emitting element is configured to emit light in response to a driving signal applied to the at least one sub-pixel, and the second light emitting element does not emit light.

14. The electronic device of claim 12, wherein another sub-pixel from among the sub-pixels do not include the repair pattern, and
wherein the first light emitting element of the tandem light emitting element of the another sub-pixel is electrically connected to the common electrode via the second light emitting element of the tandem light emitting element.

15. The electronic device of claim 14, wherein in the tandem light emitting element of the another sub-pixel, the first light emitting element and the second light emitting element are configured to concurrently emit light in response to a driving signal applied to the another sub-pixel.

16. The electronic device of claim 12, wherein a portion of a lower surface of the first light emitting element is located in an area overlapping the pixel electrode, and
wherein another portion of the lower surface of the first light emitting element is located in an area between the branch of the common electrode and the pixel electrode.

17. The electronic device of claim 16, wherein the repair pattern comprises a conductive dot covering a portion of an upper surface and a portion of a side surface of the first light emitting element of the tandem light emitting element of the at least one sub-pixel, and a portion of the branch.

18. A method for manufacturing a display device comprising sub-pixels, the method comprising:
forming a backplane substrate comprising a pixel electrode of each of the sub-pixels, and a common electrode spaced from the pixel electrode and comprising a branch extending to a periphery of the pixel electrode;
bonding a tandem light emitting element comprising a first light emitting element and a second light emitting element that are horizontally coupled, a first electrode on a lower surface of the first light emitting element, and a second electrode on a lower surface of the second light emitting element, onto the pixel electrode and the common electrode;
detecting a defect in the tandem light emitting element; and
forming a repair pattern on the tandem light emitting element in which the defect is detected,
wherein the detecting of the defect in the tandem light emitting element comprises determining a defect in each of the first light emitting element and the second light emitting element, and
when the second light emitting element from among the first light emitting element and the second light emitting element is determined to be defective, the first light emitting element is electrically connected to the common electrode by the repair pattern.

19. The method of claim 18, wherein the forming of the repair pattern comprises dispensing a conductive dot on the branch of the common electrode and the first light emitting element.

20. The method of claim 18, wherein the detecting of the defect in the tandem light emitting element comprises:
detecting light emitting characteristics of the tandem light emitting element by applying a driving signal to the tandem light emitting element of each of the sub-pixels; and
determining a defect in each of the first light emitting element and the second light emitting element by irradiating light on the tandem light emitting element that abnormally emits light in the detecting of the light emitting characteristics of the tandem light emitting element.
